(19) United States
(12) Patent Application Publication
(10) Pub. No.: US 2025/0107176 A1
(43) Pub. Date: Mar. 27, 2025

(54) Middle Dielectric Isolation in Complementary Field-Effect Transistor Devices

(71) Applicant: Taiwan Semiconductor Manufacturing Co., Ltd., Hsinchu (TW)

(72) Inventors: Cheng-Ting Chung, Hsinchu (TW); Jui-Chien Huang, Hsinchu (TW); Szuya Liao, Zhubei (TW)

(21) Appl. No.: 18/475,782

(22) Filed: Sep. 27, 2023

(51) Int. Cl. H01L 29/06; H01L 21/8238; H01L 27/092; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 64/017; H10D 84/0167; H10D 84/017; H10D 84/0188; H10D 84/038; H10D 84/85

(57) ABSTRACT

A complementary field-effect transistor (CFET) device includes: a fin; first channel regions disposed vertically over the fin; second channel regions disposed vertically over the first channel regions; an isolation structure between the first and the second channel regions; a first etch stop layer (ESL) on a lower surface of the isolation structure; a second ESL on an upper surface of the isolation structure, where the first ESL, the second ESL, the first channel regions, and the second channel regions are a same semiconductor material; first source/drain regions at opposing ends of the first channel regions; second source/drain regions at opposing ends of the second channel regions; dielectric structures at opposing ends of the isolation structure and disposed vertically between the first and the second source/drain regions; a first gate structure around the first channel regions; and a second gate structure around the second channel regions.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provides a promising new architecture that achieves improved integration density by forming nanostructure field-effect transistors (FET) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a complementary field-effect transistor (CFET) schematic in a three-dimensional view, in accordance with some embodiments.

FIGS. 2-10, 11A, 11B, and 12 are various views of a CFET device at various stages of manufacturing, in accordance with an embodiment.

FIG. 13 is a cross-sectional view of a CFET device, in accordance with another embodiment.

FIG. 14 is a cross-sectional view of a CFET device, in accordance with another embodiment.

FIG. 15 is a cross-sectional view of a CFET device, in accordance with another embodiment.

FIGS. 16A and 16B are cross-sectional views of a CFET device, in accordance with another embodiment.

FIG. 17 is a cross-sectional view of a CFET device, in accordance with another embodiment.

FIG. 18 is a cross-sectional view of a CFET device, in accordance with yet another embodiment.

FIGS. 19-26, 27A, 27B, and 28 are cross-sectional views of a CFET device at various stages of manufacturing, in accordance with an embodiment.

FIGS. 29A and 29B are cross-sectional views of a CFET device, in accordance with another embodiment.

FIGS. 30A and 30B are cross-sectional views of a CFET device, in accordance with another embodiment.

FIGS. 31A and 31B are cross-sectional views of a CFET device, in accordance with another embodiment.

FIGS. 32A and 32B are cross-sectional views of a CFET device, in accordance with another embodiment.

FIGS. 33A and 33B are cross-sectional views of a CFET device, in accordance with yet another embodiment.

FIG. 34 is a flow chart of a method of forming a CFET device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Throughout the discussion, unless otherwise specified, the same or similar reference numerals in different figures refer to the same or similar element formed by a same or similar material(s) using the same or similar formation method(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, CFETs are formed. The disclosed methods allow for various shapes and structures for the isolation structures of the CFETs, which are disposed between the upper nanostructures and the lower nanostructures of the CFETs. The various shapes and structures allow the CFETs to satisfy different design targets and performance requirements.

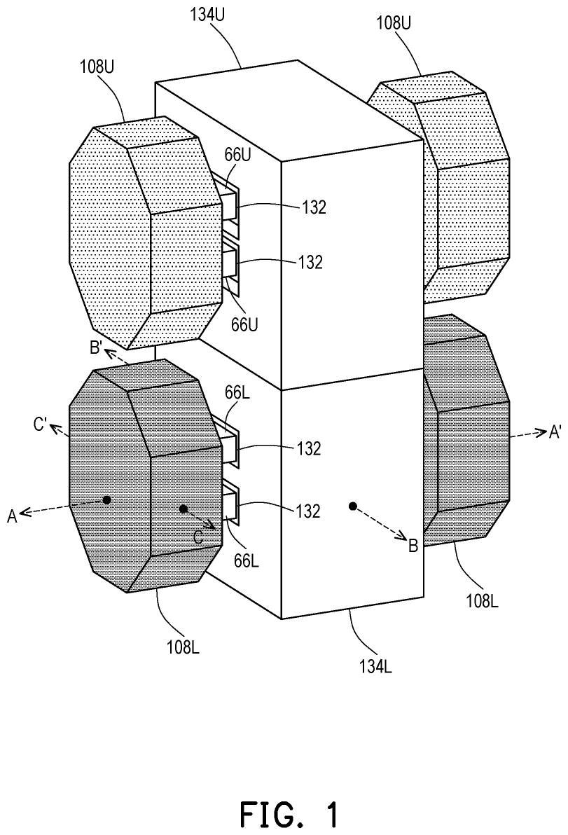

FIG. 1 illustrates an example of a CFET schematic, in accordance with some embodiments. FIG. 1 is a three-dimensional view, where some features of the CFETs are omitted for illustration clarity.

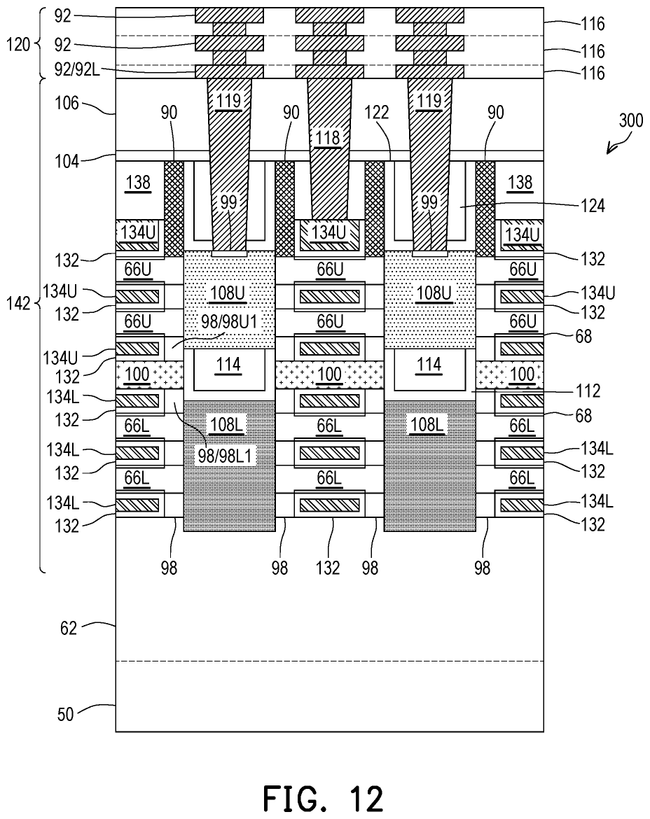

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Note that the structure of CFETs also allows nanostructure-FETs of the same device type to be vertically stacked to form semiconductor devices. Therefore, the terminology CFET is used herein as a generic term to refer to the vertically stacked nature of the device structure, and is not limited to vertically stacked transistors of opposite device types. Each of the nanostructure-FETs include semiconductor nanostructures 66 (including lower semiconductor nanostructures 66L and upper semiconductor nanostructures 66U), where the semiconductor nanostructures 66 act as channel regions (also referred to as channel layers, semiconductor channels regions, or semiconductor channel layers) for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A nanostructure isolation material (not explicitly illustrated in FIG. 1, see 100 in FIGS. 12A and 12B) may be used to separate and electrically isolate the upper semiconductor nanostructures 66U from the lower semiconductor nanostructures 66L. For simplicity, a semiconductor nanostructure may also be referred to as a nanostructure hereinafter.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

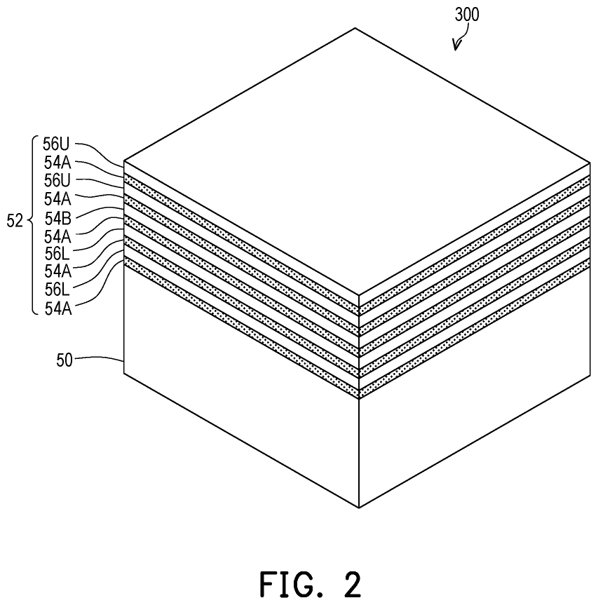

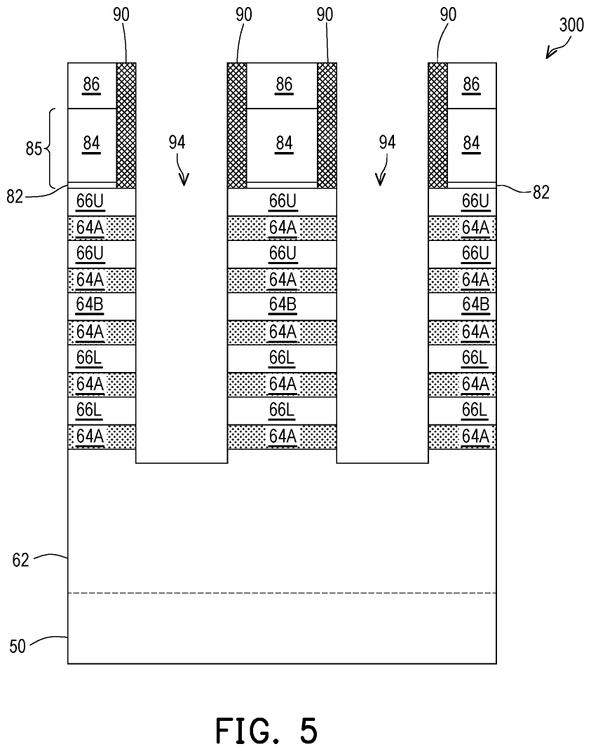

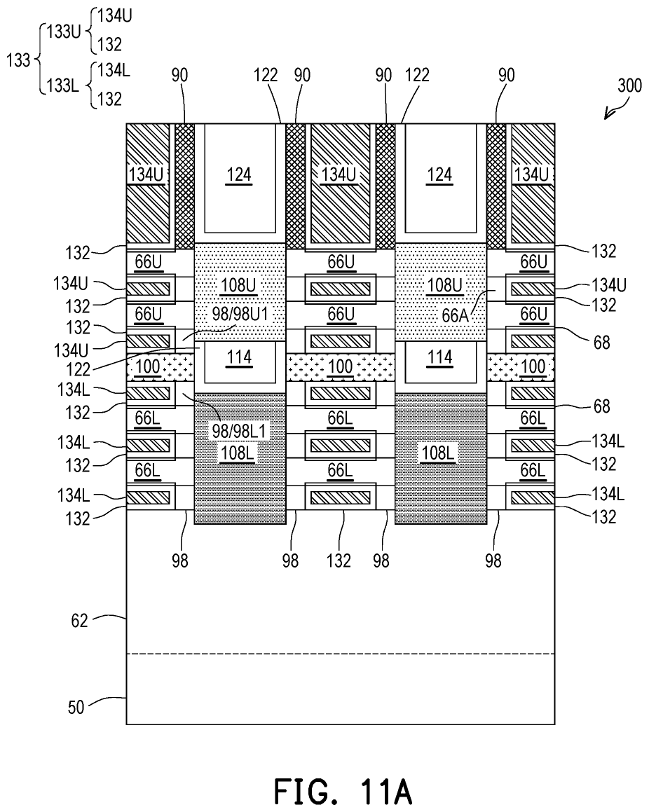

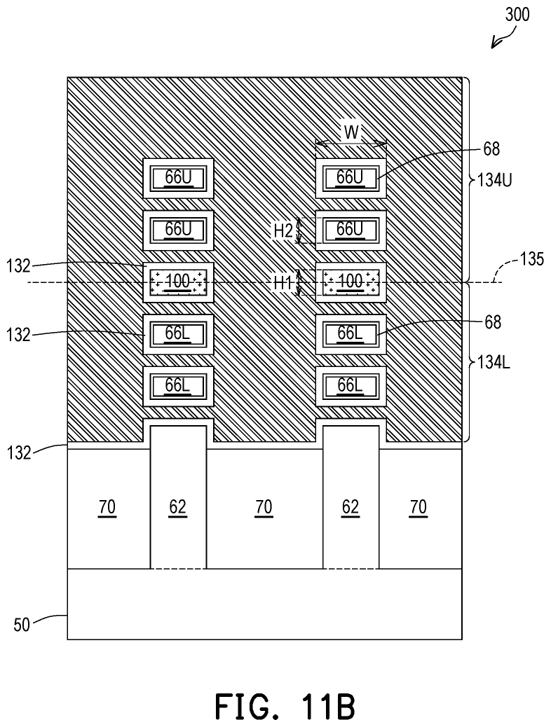

FIGS. 2-10, 11A, 11B, and 12 are various views (e.g., three-dimensional view, cross-sectional view) of a CFET device 300 at various stages of manufacturing, in accordance with an embodiment. FIGS. 2, 3, and 4 are three-dimensional views showing a similar three-dimensional view as FIG. 1. FIGS. 5-10, 11A, and 12 illustrate cross-sectional views along a similar cross-section as reference cross-section A-A′ in FIG. 1. FIG. 11B illustrates a cross-sectional view along a similar cross-section as reference cross-section B-B′ in FIG. 1. Throughout the discussion herein, figures with the same numeral but different alphabets (e.g., FIGS. 11A and 11B) illustrate different views (e.g., along different cross-sections) of the same semiconductor device at the same stage of processing.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B, and are interleaved with each other (e.g., forming an alternating layer pattern). The upper semiconductor layers 56U and another subset of the first dummy layers 54A are disposed above the second dummy layer 54B, and are interleaved with each other. In the example of FIG. 2, the second dummy layer 54B is in contact with the first dummy layer 54A immediately above it, and is in contact with the first dummy layer 54A immediately below it. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including seven of the dummy layers 54 and five of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. In some embodiments, the semiconductor layers 56 is formed of a group IV-V material or a group III-V material. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of each of the first dummy layers 54A. In some embodiments, the second dummy layer 54B has a large thickness, such as a greater thickness than each of the first dummy layers 54A. Forming the second dummy layer 54B to a large thickness allows the second dummy layer 54B to be more easily removed in subsequently processing. Additionally, the thickness of each of the semiconductor layers 56 may be different (e.g., greater or less) than the thickness(es) of each of the first dummy layers 54A and/or the second dummy layer 54B. In some embodiments, each of the semiconductor layers 56 may be thicker than each of the dummy layers 54.

In some embodiments, the first dummy layers 54A are formed of silicon-germanium with a first germanium atomic percentage, the second dummy layer 54B is formed of silicon-germanium with a second germanium atomic percentage that is higher than the first germanium atomic percentage. The difference between the second germanium atomic percentage and the first germanium atomic percentage may be higher than, e.g., about 10 percent or 30 percent, and may be in the range between about 30 percent and about 70 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

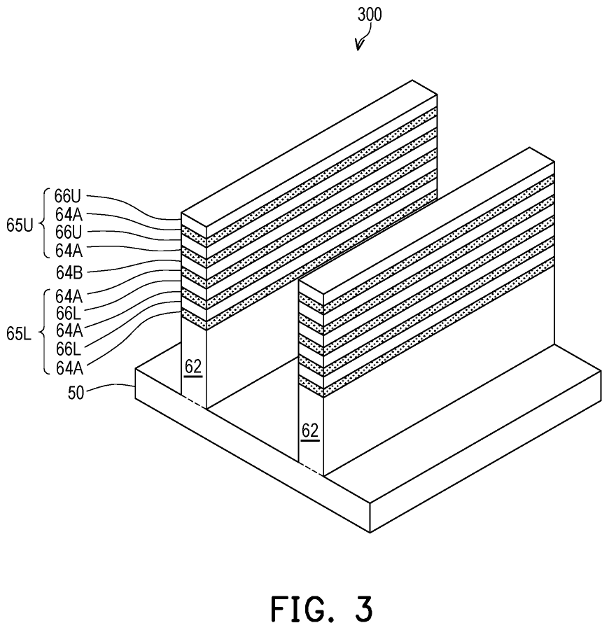

In FIG. 3, fins 62 are formed in the substrate 50 and nanostructures 64, 66 (including first dummy nanostructures 64A, second dummy nanostructures 64B, lower semiconductor nanostructures 66L, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from the lower semiconductor layers 56L, and the upper semiconductor nanostructures 66U from the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66. The nanostructures (e.g., 64A and 66L) below the second dummy nanostructures 64B may be collectively referred to as lower nanostructures 65L, and the nanostructures (e.g., 64A and 66U) above the second dummy nanostructures 64B may be collectively referred to as upper nanostructures 65U. In the example of FIG. 3, each of the second nanostructures 64B is interposed between a lower nanostructure 65L and an upper nanostructure 65U.

As subsequently described in greater detail, the dummy nanostructures 64 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs. The second dummy nanostructures 64B will be subsequently replaced with isolation structures. The isolation structures may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in cross-sectional view.

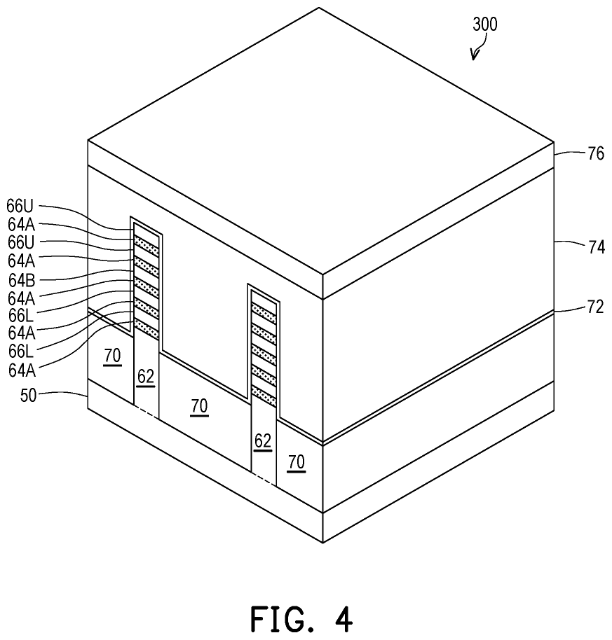

In FIG. 4, isolation regions 70 are formed adjacent to the fins 62. The isolation regions 70 may be formed by depositing an insulating material over the substrate 50, the fins 62, and nanostructures 64, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 64, 66). For example, an oxide removal using, for example, dilute hydrofluoric (dHF) acid may be used.

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

Next, in FIG. 5, the mask layer 76 is patterned using acceptable photolithography and etching techniques to form masks 86. The pattern of the masks 86 is then transferred to the dummy gate layer 74 and to the dummy dielectric layer 72 to form dummy gates 84 and dummy dielectrics 82, respectively. The dummy gates 84 and the dummy dielectrics 82 are collectively referred to as dummy gate stacks 85. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIG. 5, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as CVD, ALD, or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Fin spacers may also be formed as part of forming the gate spacers 90.

Source/drain recesses 94 (also referred to as source/drain openings) are formed in the nanostructures 64, 66, and the fins 62. Epitaxial source/drain regions will be subsequently formed in the source/drain recesses 94. The source/drain recesses 94 may extend through the nanostructures 64, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 66, and the substrate 50 using anisotropic etching processes, such as RIE, NBE, or the like. The gate spacers 90 and the dummy gates 84 mask portions of the nanostructures 64, 66, and the fins 62 during the etching processes used to form the source/drain recesses 94. A single etch process or multiple etch processes may be used to etch each layer of the nanostructures 64, 66, and the fins 62. Timed etch processes may be used to stop the etching of the source/drain recesses 94 after the source/drain recesses 94 reach a desired depth.

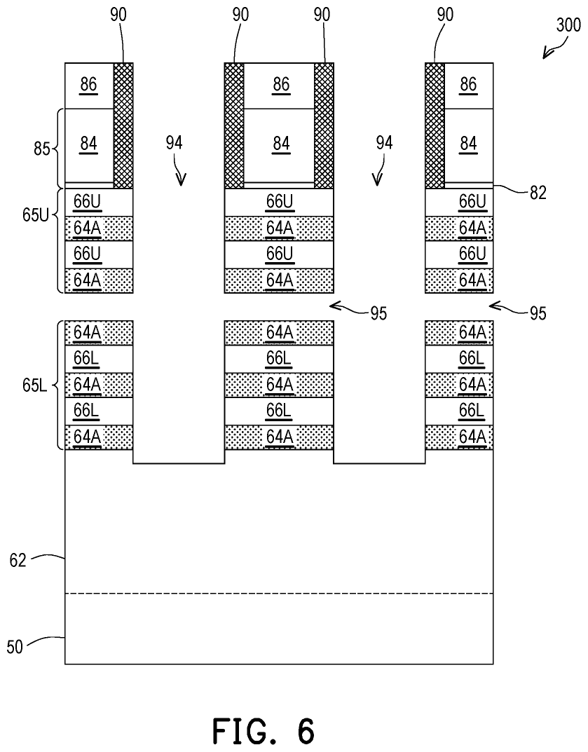

Next, in FIG. 6, the second dummy nanostructures 64B are removed. In some embodiments, a selectively etching process is performed using an etchant selective to (e.g., having a higher etching rate for) the material of the second dummy nanostructures 64B, such that the second dummy nanostructures 64B are completely removed without substantially attacking other materials of the NFET device. The selective etching process is an isotropic etching process, in an example embodiment. In some embodiments where the second dummy nanostructures 64B are formed of germanium or silicon germanium with a high germanium atomic percentage, the first dummy nanostructures 64A are formed of silicon germanium with a low germanium atomic percentage, and the semiconductor nanostructures 66 are formed of silicon free from germanium, the selective etching process may comprise a dry etch process using chlorine gas, with or without a plasma. Because the dummy gate stacks 85 warp around sidewalls of the semiconductor nanostructures 66 and 64 (see FIG. 4), the dummy gate stacks 85 may support the upper nanostructures 65U so that the upper nanostructures 65U do not collapse upon removal of the second dummy nanostructures 64B. After the removal of the second dummy nanostructures 64B, gaps 95 (e.g., empty spaces) are formed between the upper nanostructures 65U and lower nanostructures 65L.

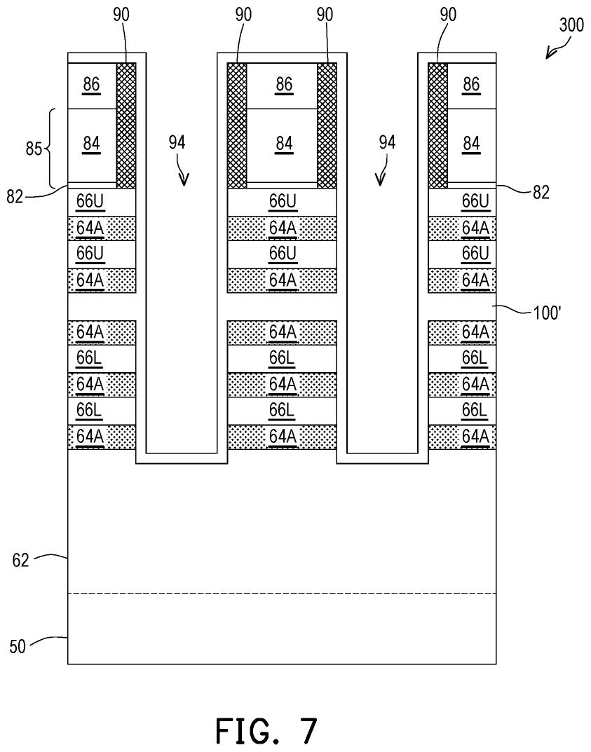

Next, in FIG. 7, a dielectric material 100′ is formed (e.g., conformally) over the CEFT device of FIG. 6. The dielectric material 100′ is formed to line the bottoms and sidewalls of the source/drain recesses 94, and fill the gaps 95. In some embodiments, the dielectric material 100′ is a suitable dielectric material such as silicon oxide, silicon nitride, silicon oxynitride, silicon carbonitride, silicon oxycarbide, aluminum oxide, hufnium oxide, zirconium oxide, the like, combinations thereof, or multiplayers thereof. The dielectric material 100′ may be a single layer material, or may comprise a plurality of sub-layers, such as having a bi-layered structure, or a tri-layered structure. A suitable formation method, such as CVD, PVD, ALD, or the like, may be performed to form the dielectric material 100′. A thickness of the dielectric layer 100′ may be between about 2 nm and about 20 nm, as an example.

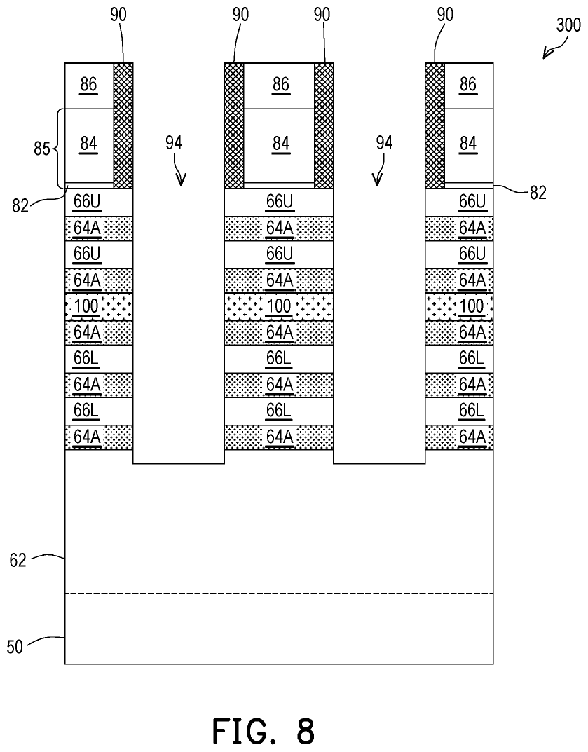

Next, in FIG. 8, an etching process is performed to remove portions of the dielectric material 100′ that are disposed outside of the gaps 95. The etching process may be anisotropic (e.g., an anisotropic plasma etching process), although a suitable isotropic etching process may also be used. After the etching process, remaining portions of the dielectric material 100′ inside the gaps 95 form isolation structures 100 (also referred to as dielectric isolation structures). In the example of FIG. 8, sidewalls of the isolation structures 100 are straight and are flush with sidewalls of the nanostructures 64 and 66. In other embodiments, the sidewalls of the isolation structures 100 may be curved (e.g., concave, or convex), and may not align with the sidewalls of the nanostructures 64 and 66. These and other variations are fully intended to be included within the scope of the present disclosure.

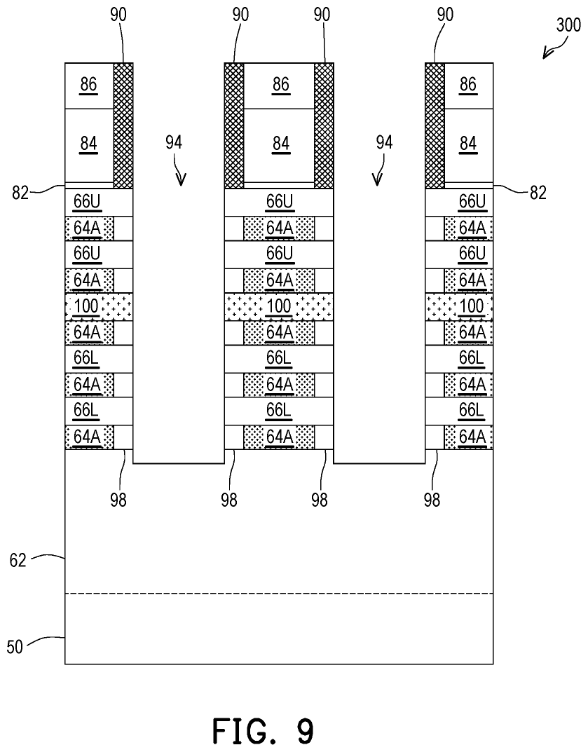

Next, in FIG. 9, inner spacers 98 are formed. Forming the inner spacers 98 may include an etching process that laterally etches the first dummy nanostructures 64A. The etching process may be isotropic and may be selective to the material of the first dummy nanostructures 64A, so that the first dummy nanostructures 64A are etched at a faster rate than the semiconductor nanostructures 66. Although sidewalls of the dummy nanostructures 64A are illustrated as being straight after the etching, the sidewalls may be concave or convex.

The inner spacers 98 are formed on sidewalls of the recessed first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etching processes, such as the etching processes used to form gate structures. Isolation structures 100, on the other hand, are used to isolate the upper semiconductor nanostructures 66U (collectively) from the lower semiconductor nanostructures 66L (collectively). Further, the isolation structures 100 may define the boundaries of the lower nanostructure-FETs and the upper nanostructure-FETs.

The inner spacers 98 may be formed by conformally depositing an insulating material in the source/drain recesses 94, and on sidewalls of the recessed first dummy nanostructures 64A, and then etching the insulating material. The insulating material may be a hard dielectric material, e.g., a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining along the sidewalls of the (recessed) first dummy nanostructures 64A (thus forming the inner spacers 98).

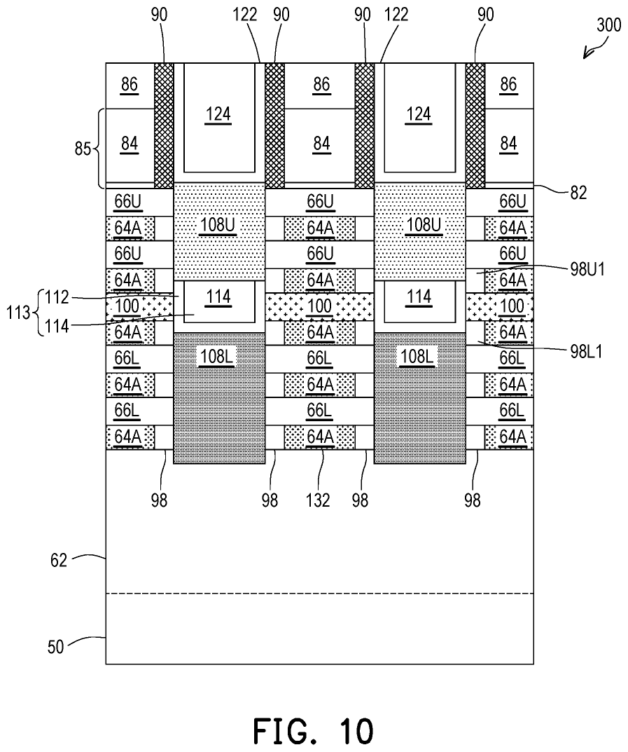

Next, in FIG. 10, lower epitaxial source/drain regions 108L and upper epitaxial source/drain regions 108U are formed. The lower epitaxial source/drain regions 108L are formed in the lower portions of the source/drain recesses 94. The lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the dummy nanostructures 64A, which will be replaced with replacement gates in subsequent processes.

The lower epitaxial source/drain regions 108L are epitaxially grown, and have a conductivity type that is suitable for the device type (p-type or n-type) of the lower nanostructure-FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent undesired epitaxial growth on the upper semiconductor nanostructures 66U. After the lower epitaxial source/drain regions 108L are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 64 and 66. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 66U are exposed. The first ILD 114 and the first CESL 112 after the recessing may be collectively referred to as dielectric structures 113. In the illustrated embodiment, the dielectric structures 113 extend along sidewalls of the isolation structures 100, along sidewalls of inner spacers 98U1 (e.g., inner spacers 98 over and contacting the isolation structures 100), and along sidewalls of the inner spacers 98L1 (e.g., inner spacers 98 below and contacting the isolation structures 100). Along the vertical direction of FIG. 10, each dielectric structure 113 is disposed below the upper surface of the inner spacer 98U1 and above the lower surface of the inner spacer 98L1.

Upper epitaxial source/drain regions 108U are then formed in the upper portions of the source/drain recesses 94. The upper epitaxial source/drain regions 108U may be epitaxially grown from exposed surfaces of the upper semiconductor nanostructures 66U. The materials of upper epitaxial source/drain regions 108U may be selected from the same candidate group of materials for forming lower epitaxial source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. Adjacent upper epitaxial source/drain regions 108U may remain separated after the epitaxy process or may be merged. As discussed above, the lower nanostructure-FET and the upper nanostructure-FET of the CFET device may be of the same device type (e.g., n-type or p-type), or may be of different device types.

After the upper epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate stacks 85.

Next, in FIGS. 11A-11B, the dummy gate stacks 85 are replace by replacement gate structures in a replacement gate process. The mask 86 (if not removed already) is removed, e.g., by a CMP process. Next, the dummy gate stacks 85 are removed in one or more etching steps, so that recesses are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the recesses exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

FIG. 11B shows the CFET device 300 of FIG. 11A, but along cross-section B-B′ of FIG. 1. As illustrated in FIG. 11B, the isolation structures 100 and the nanostructures 66 have a same width W. The isolation structures 100 have a height H1, and the nanostructures 66 have a height H2. The height H1 is larger than the height H2, in some embodiments, which may offer better isolation between the nanostructures 66U and 66L, and may tolerate larger process variation for the thickness of the dielectric structures 113. In other embodiments, the height H1 is equal to, or smaller than the height H2. The height H1 may be between about 5 nm and about 30 nm, and the height H2 may be between about 3 nm and about 10 nm.

Next, an interfacial layer 68 is formed at the exterior surfaces of the nanostructures 66. In some embodiments, the interfacial layer 68 is formed of an oxide of a group II-VI material or an oxide of a group IV material. In the illustrated embodiment, the interfacial layer 68 is an oxide of the material of the nanostructures 66, and is formed by an oxidization process (e.g., a thermal oxidization process). In other words, the interfacial layer 68 is formed by converting (e.g., oxidizing) exterior portions of the nanostructures 66 into an oxide (e.g., silicon oxide) of the material (e.g., silicon) of the nanostructures 66. As a result, the interfacial layer 68 is not formed on, e.g., the isolation structures 100 and the isolation regions 70, in the illustrated embodiment. A thickness of the interfacial layer 68 may be between about 0.5 nm and about 2 nm, as an example.

In the cross-sectional view of FIG. 11B, the interfacial layer 68 surrounds (e.g., encircles) the nanostructures 66, and no interfacial layer 68 is formed on the isolation structures 100. Note that in FIG. 11A, no interfacial layer 68 is formed at surfaces of end portions 66A of the nanostructures 66, which end portions 66A are disposed between vertically adjacent inner spacers 98. This is because the end portions 66A are not exposed to the openings 128, thus not oxidized by the oxidization process.

Still referring to FIGS. 11A and 11B, next, a gate dielectric layer 132 (also referred to as gate dielectrics) is formed (e.g., conformally) over the interfacial layer 68 and along sidewalls of the isolation structures 100, such that the gate dielectric layer 132 conformally lines the recesses between gate spacers 90 and lines the openings between the nanostructures 66. Specifically, the gate dielectric layer 132 is formed on the top surfaces of the fins 62; along the top surfaces, the sidewalls, and the bottom surfaces of the semiconductor nanostructures 66 (on the interfacial layer 68); along the top surfaces, the sidewalls, and the bottom surfaces of the isolation structures 100; and along the sidewalls of the gate spacers 90. The gate dielectric layer 132 wraps around all (e.g., four) sides of the semiconductor nanostructures 66 and the isolation structures 100. The gate dielectric layer 132 may also be formed on the top surfaces of the second ILD 124 and the gate spacers 90, and may be formed on the sidewalls of the fins 62 (e.g., in embodiments where the top surfaces of the isolation regions 70 are below the top surfaces of the fins 62).

The gate dielectric layer 132 may include an oxide such as silicon oxide or a metal oxide, a silicate such as a metal silicate, combinations thereof, multi-layers thereof, or the like. The gate dielectric layer 132 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 132 may include molecular-beam deposition (MBD), ALD, PECVD, and the like. A thickness of the gate dielectric layer 132 may be between about 1 nm and about 5 nm, as an example.

Next, lower gate electrodes 134L are formed on the gate dielectrics 132 around the lower semiconductor nanostructures 66L. For example, the lower gate electrodes 134L wrap around the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a gate fill material (e.g., a metal or metal-containing material).

The lower gate electrodes 134L are formed of material(s) that are suitable for the device type of the lower nanostructure-FETs. For example, the lower gate electrodes 134L may include one or more work function tuning layer(s) formed of material(s) that are suitable for the device type of the lower nanostructure-FETs. In some embodiments, the lower gate electrodes 134L include an n-type work function tuning layer, which may be formed of titanium aluminum, titanium aluminum carbide, tantalum aluminum, tantalum carbide, combinations thereof, or the like. In some embodiments, the lower gate electrodes 134L include a p-type work function tuning layer, which may be formed of titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 134L may be formed by conformally depositing one or more gate electrode layer(s), then recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 134L may expose the upper semiconductor nanostructures 66U.

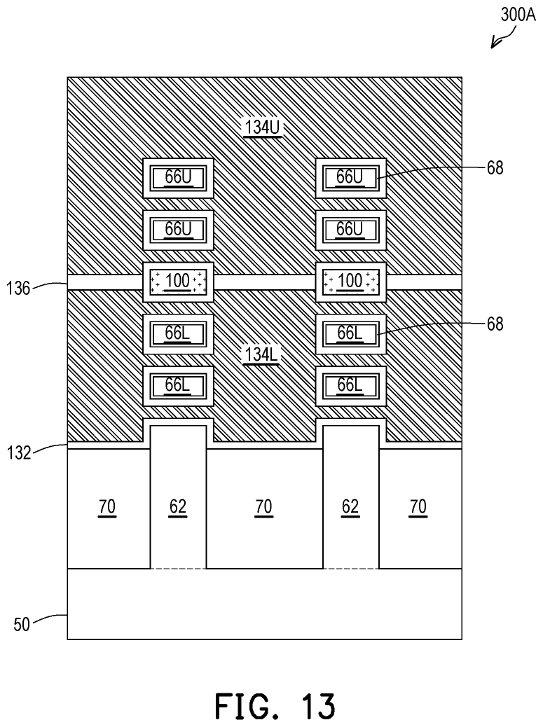

In some embodiments, isolation layers (not illustrated in FIGS. 11A and 11B, see, e.g., 136 in FIG. 13) may be optionally formed on the lower gate electrodes 134L. The isolation layers act as isolation features between the lower gate electrodes 134L and subsequently formed upper gate electrodes 134U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 66U.

Next, upper gate electrodes 134U are formed on the isolation layers described above (if present) or on the lower gate electrodes 134L. The upper gate electrodes 134U are disposed between the upper semiconductor nanostructures 66U, and wrap around the upper semiconductor nanostructures 66U. The upper gate electrodes 134U may be formed of the same candidate materials and candidate processes for forming the lower gate electrodes 134L. The upper gate electrodes 134U are formed of material(s) that are suitable for the device type of the upper nanostructure-FETs. For example, the upper gate electrodes 134U may include one or more work function tuning layer(s) formed of material(s) that are suitable for the device type of the upper nanostructure-FETs. Although single-layered gate electrodes 134U are illustrated, the upper gate electrodes 134U may include any number of work function tuning layers, any number of barrier layers, any number of glue layers, and a gate fill material.

Additionally, a removal process is performed level top surfaces of the upper gate electrodes 134U and the second ILD 124. In some embodiments, a planarization process such as a chemical mechanical polish (CMP), an etch-back process, combinations thereof, or the like may be utilized as the removal process. After the planarization process, the top surfaces of the upper gate electrodes 134U, the gate dielectrics 132, the second ILD 124, and the gate spacers 90 are substantially coplanar (within process variations). Each respective pair of a gate dielectric 132 and a gate electrode 134 (including an upper gate electrode 134U and/or a lower gate electrode 134L) may be collectively referred to as a “gate structure” 133 (including upper gate structures 133U and lower gate structures 133L). Each gate structure 133 (may also be referred to as a replacement gate structure, or a metal gate structure) extends along multiple sides (e.g., a top surface, sidewalls, and a bottom surface) of a channel region of a semiconductor nanostructure 66. The lower gate electrode 134L may also extend along sidewalls and/or a top surface of a fin 62.

In the example of FIG. 11B, no isolation layer is formed, and the upper gate electrodes 134U and the lower gate electrodes 134L are in directly contact. The dashed line 135 in FIG. 11B, which is disposed between the upper surface and the lower surface of the isolation structures 100, is used as a conceptual delineation between the upper gate electrode 134U and the lower gate electrode 134L, with the understanding that the gate fill material may extend continuously without an interface from the upper gate electrode 134U to the lower gate electrode 134L. Note that the isolation layer, if formed, is not in the cross-section of FIG. 11A, thus is not visible in the cross-section of FIG. 11A.

Next, in FIG. 12, gate masks 138 are formed over the gate structures 133. The formation process may include recessing gate structures 133, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 124.

Next, an etch stop layer (ESL) 104 and a third ILD 106 are the formed over the second ILD 124 and the gate masks 138. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Next, source/drain contact openings are formed to extend through the ESL 104, the third ILD 106, the second ILD 124 and the second CESL 122 to expose the upper epitaxial source/drain regions 108U. Similarly, gate contact openings are formed to extend through the ESL 104, the third ILD 106, and the gate masks 138 to expose the upper gate electrode 134U. Next, silicide regions 99 are formed on the upper epitaxial source/drain regions 108U, and source/drain contact plugs 119 are formed on the silicide regions 99 to electrically couple to the upper epitaxial source/drain regions 108U. In addition, gate contact plugs 118 are formed in the gate contact openings to electrically couple to the upper gate electrode 134U.

In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the upper epitaxial source/drain regions 108U, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The layers of the CFET device 300 disposed between upper portions of the fins 62 and the third ILD 106 are collectively referred to as the device layer 142 of the CFET device.

Next, a front-side interconnect structure 120 is formed on the device layer 142. The front-side interconnect structure 120 includes dielectric layers 116 and layers of conductive features 92 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 92 may include conductive lines and vias, which may be formed using, e.g., damascene processes. Conductive features 92 may include metal lines and metal vias, which may include diffusion barriers and a copper containing material over the diffusion barriers. There may also be aluminum pads over and electrically connected to the metal lines and vias. Depending on how the respective die is to be packaged, the top surface features among the conductive features 92 may include bond pads, metal pillars, solder regions, and/or the like. In some embodiments, contacts to the lower gate structures 133L and the lower epitaxial source/drain regions 108L may be made through a backside of the device layer 142 (e.g., a side opposite to the front-side interconnect structure 120).

FIG. 13 is a cross-sectional view of a CFET device 300A, in accordance with another embodiment. The CFET device 300A is similar to the CFET device 300, but with isolations layers 136 formed between the lower gate electrode 134L and the upper gate electrode 134U. The cross-sectional view of the CFET device 300A along cross-section A-A′ is the same as or similar to FIG. 12, thus not repeated. As discussed above, the isolation layers 136 may be formed after the lower gate electrode 134L is formed and before the upper gate electrode 134U is formed. The isolation layers 136 may be formed by conformally depositing a dielectric material (e.g., silicon oxide, silicon nitride, silicon oxynitride, silicon oxycarbonitride, combinations thereof, or the like) on the lower gate electrode 134L and subsequently recessing the dielectric material to expose the upper semiconductor nanostructures 66U. The isolation layer 136 is between an upper surface and a lower surface of the isolation structure 100, in the illustrated embodiment. The isolation layer 136 electrically isolates the upper gate electrode 134U from the lower gate electrode 134L, and allows the upper gate electrode 134U and the lower gate electrode 134L to be controlled by different gate control voltages.

Additional embodiments are discussed hereinafter. The additional embodiment CFET devices may be formed by modifying the processing steps for the fabrication of CFET device 300. Skilled artisan, upon reading the present disclosure, would readily be able to modify the processing steps for the fabrication of CFET device 300 to form the additional embodiment CFET devices. Note that for each of the subsequent embodiments discussed, the isolation layer 136 between the lower gate electrode 134L and the upper gate electrode 134U, if present, may be removed to represent another embodiment, as skilled artisans readily appreciate.

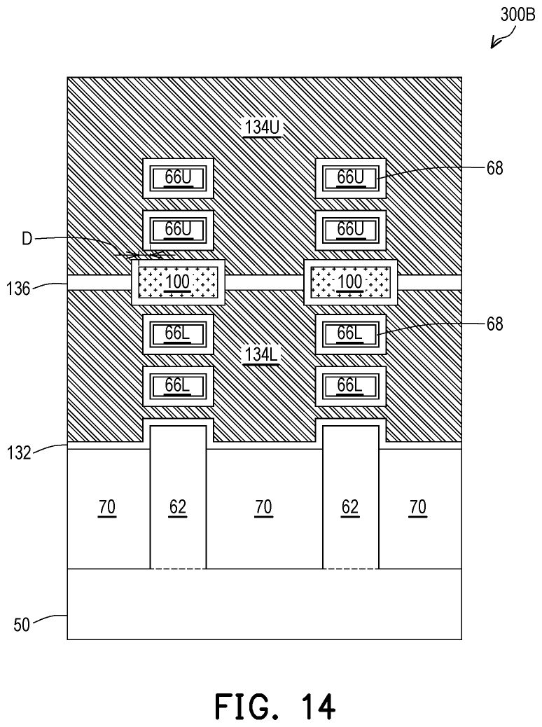

FIG. 14 is a cross-sectional view of a CFET device 300B, in accordance with another embodiment. The CFET device 300B is similar to the CFET device 300A, but the isolation structures 100 are wider than the nanostructures 66. In some embodiments, after the first dummy nanostructures 64A are removed to release the nanostructures 66 (see FIGS. 11A and 11B), a trimming process (e.g., an etching process) is performed to reduce the size (e.g., width and/or height) of the nanostructures 66. The trimming process increases the spacing between adjacent nanostructures 66, which advantageously makes it easier to form subsequent layers of materials (e.g., gate dielectrics, work function layer(s), and gate fill material) between the nanostructures 66. Due to the trimming process selectively etching the nanostructures 66, the isolation structure 100 is wider than the nanostructures 66 at each side by about 1 nm to about 5 nm. In other words, a lateral offset D between a sidewall of the isolation structure 100 and a respective sidewall (e.g. a close sidewall) of the nanostructure 66 is between about 1 nm and about 5 nm. The cross-sectional view of the CFET device 300B along cross-section A-A′ is the same as or similar to the CFET device 300 in FIG. 12, thus not repeated.

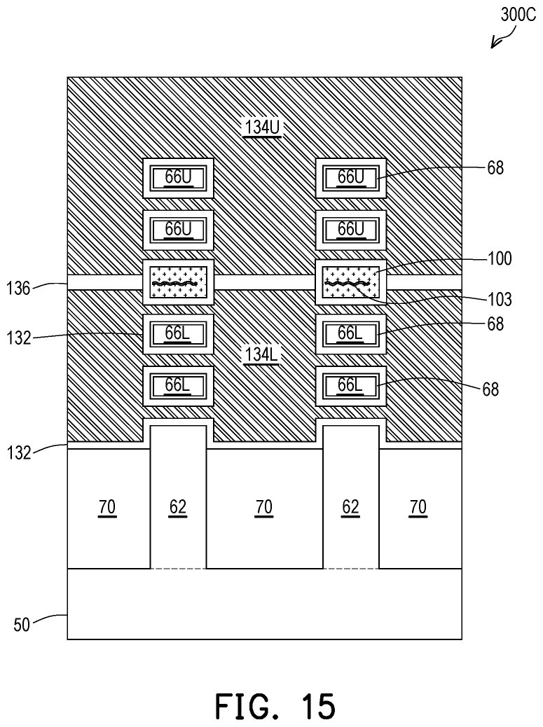

FIG. 15 is a cross-sectional view of a CFET device 300C, in accordance with another embodiment. The CFET device 300C is similar to the CFET device 300A, but with a seam 103 (e.g., an air gap, or an empty space) in each of the isolation structures 100. The seam 103 is formed in the processing of FIG. 7, when the dielectric material 100′ does not completely fill the gaps 95 between the upper nanostructures 65U and the lower nanostructures 65L, e.g., due to the difficulty in filling the gaps 95 with small heights. The cross-sectional view of the CFET device 300C along cross-section A-A′ is similar to the CFET device 300 in FIG. 12, but with the seam 103 in the isolation structure 100.

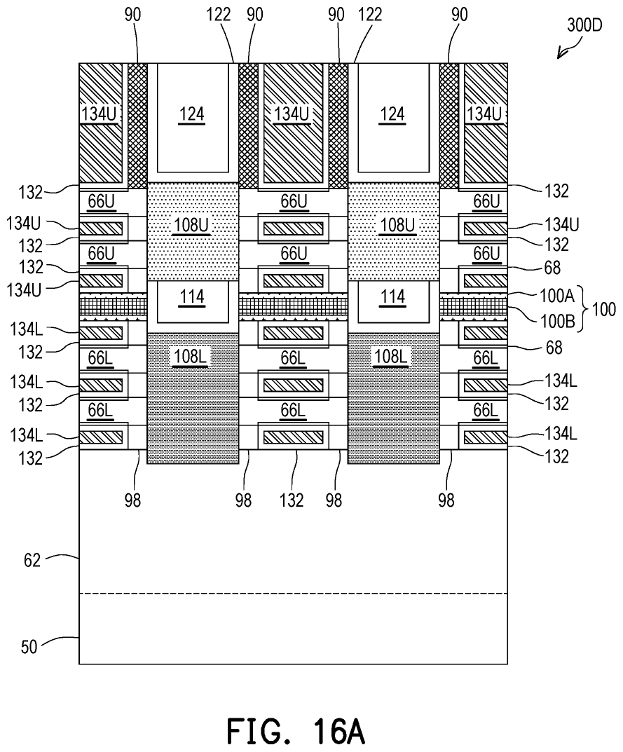

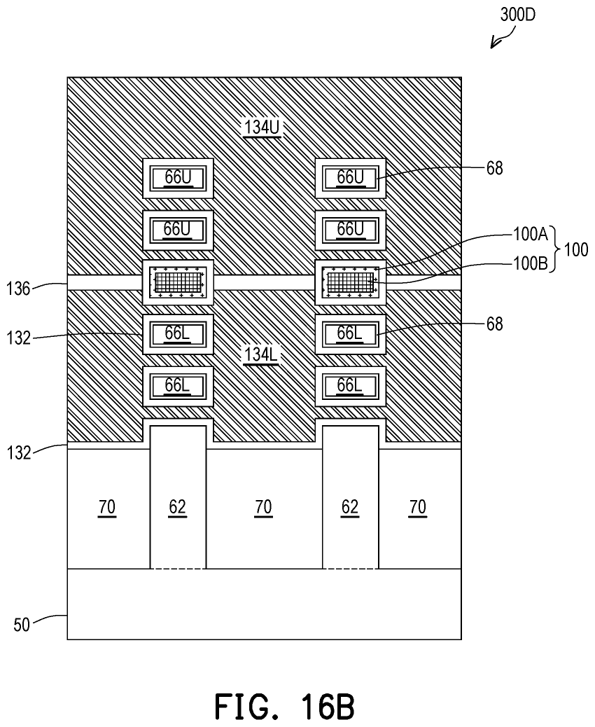

FIGS. 16A and 16B are cross-sectional views of a CFET device 300D, in accordance with another embodiment. The CFET device 300D is similar to the CFET device 300A, but the isolation structures 100 are formed of two different materials (e.g., 100A and 100B).

In some embodiments, to form the isolation structure 100 of the CFET device 300D, in the processing of FIG. 7, a first dielectric material 100A is formed to line the source/drain recesses 94 and the gaps 95. The first dielectric material 100A is formed using a material with better etching resistance (e.g., silicon nitride) and may also function as an adhesion layer for the subsequently formed second dielectric material 100B. The first dielectric material 100A does not complete fill the gaps 95, and instead, only partially fills the gaps 95, with the center region of the gaps 95 unfilled. A thickness of the first dielectric material 100A may be between about 1 nm and 10 nm, as an example. Next, the second dielectric material 100B is formed to fill the remaining portions of the gaps 95 left by the first dielectric material 100A. The second dielectric material 100B is formed using a material with better flowability, such as silicon oxide formed by a FVCD process. A thickness of the second dielectric material 100B may be between about 2 nm and 10 nm, as an example. The bi-layered structure for the isolation structures 100 reliably avoids or reduces the occurrence of seams (see, e.g., 103 in FIG. 15) in the isolation structures 100. As illustrated in FIGS. 16A and 16B, the first dielectric material 100A encircles (e.g., surrounds) the second dielectric material 100B, and contacts the gate dielectric layer 132.

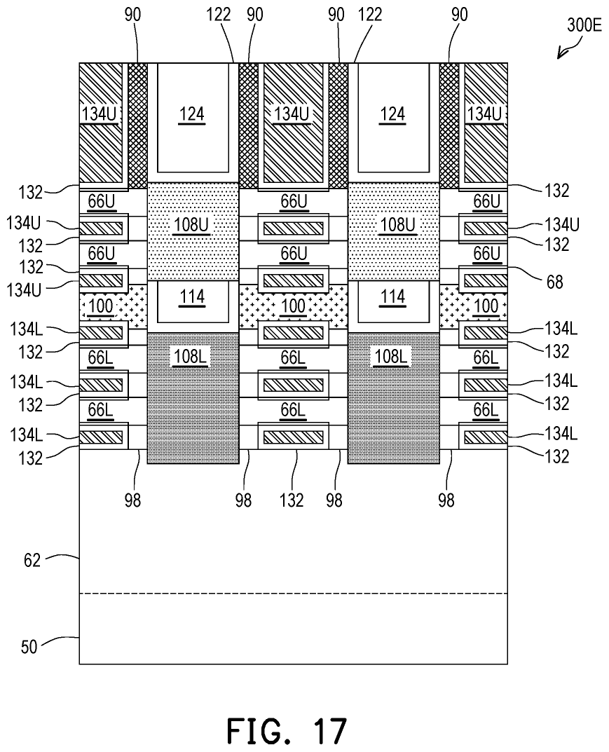

FIG. 17 is a cross-sectional view of a CFET device 300E, in accordance with another embodiment. The CFET device 300E is similar to the CFET device 300, but the isolation structures 100 have a dumbbell-shaped cross-section in FIG. 17. In particular, end portions of each isolation structures 100 (e.g., portions between, and contacting, the inner spacers 98) are thicker than center portions (e.g., portions between, and contacting, the gate dielectric layer 132) of the isolation structure 100. The dumbbell shape may be a result of the center portions of the isolation structures 100 being etched during the etching process to remove the first dummy nanostructures 64 to release the nanostructures 66, and/or the etching process to trim the nanostructures 66. In an embodiment, the end portions of the isolation structure 100 may be thicker than the center portions of the isolation structure 100 by a total of about 2 nm to about 10 nm, such that a vertical offset between an upper surface (or a lower surface) of the end portion of the isolation structure 100 and an upper surface (or a lower surface) of the center portion of the isolation structure 100 is between about 1 nm and about 5 nm. The cross-sectional view of the CFET device 300E along cross-section B-B′ is the same as or similar to the CFET device 300 in FIG. 11B, details are not repeated here.

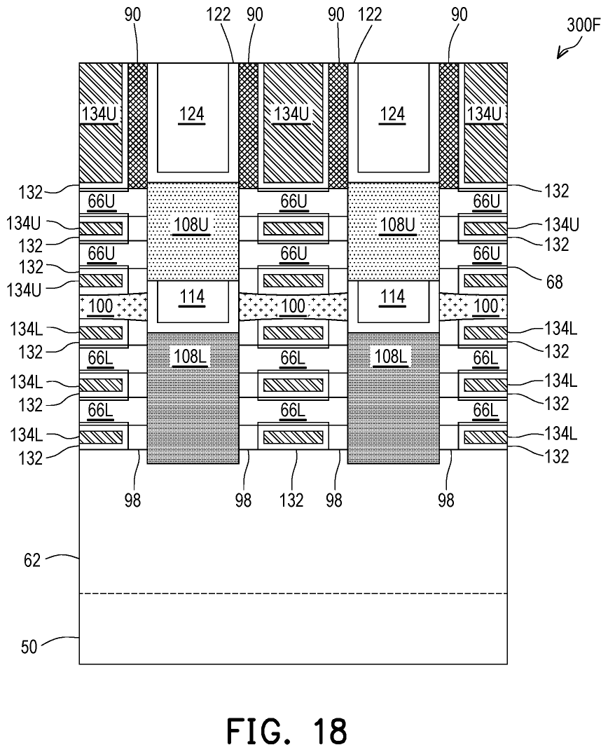

FIG. 18 is a cross-sectional view of a CFET device 300F, in accordance with yet another embodiment. The CFET device 300F is similar to the CFET device 300, but the isolation structures 100 have a drum shape with curved upper surfaces and curved lower surfaces. In particular, end portions of each isolation structures 100 (e.g., portions between, and contacting, the inner spacers 98) are thicker than center portions (e.g., portions between, and contacting, the gate dielectric layer 132) of the isolation structure 100. In some embodiments, in the processing of FIG. 6, the etching process performed to remove the second dummy nanostructures 64B may also remove some portions of the first dummy nanostructures 64A. For example, corner portions of the first dummy nanostructures 64A contacting the second dummy nanostructures 64B are removed more than center portions of the first dummy nanostructures 64A, thereby causing the drum shape of the isolation structures 100 after the gaps 95 are filled. The cross-sectional view of the CFET device 300F along cross-section B-B′ is the same as or similar to the CFET device 300 in FIG. 11B, details are not repeated here.

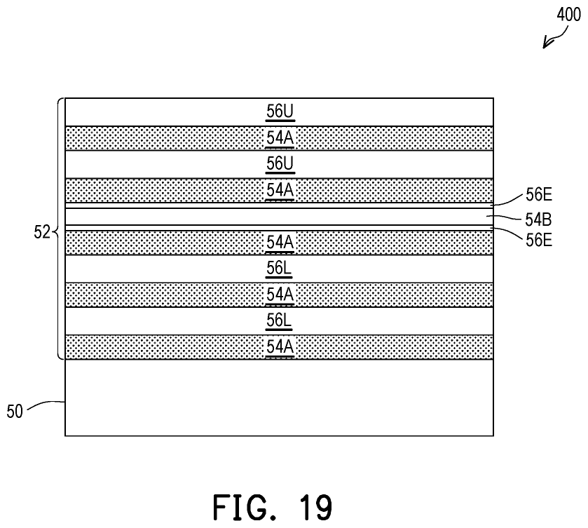

FIGS. 19-26, 27A, 27B, and 28 are various views (e.g., three dimensional view, cross-sectional view) of a CFET device 400 at various stages of manufacturing, in accordance with an embodiment. The CFET device 400 is similar to the CFET device 300, but with etch stop layers 56E formed above and below the second dummy layer 54B in the multi-layer stack 52, such that in subsequent processing, each of the second dummy nanostructures 64B formed is sandwiched between two ESLs 66E. Details are discussed below. Note that for simplicity, the discussion below regarding the CFET device 400 focuses on the differences between the fabrication processes of the CFET device 400 and the CFET device 300, while processing steps common to both the CFET devices 400 and 300 may be mentioned briefly or omitted.

FIG. 19 illustrates the cross-sectional view of a multi-layer stack 52, which is similar to the multi-layer stack 52 in FIG. 2, but with etch stop layers (ESLs) 56E formed above and below the second dummy layer 54B in the multi-layer stack 52. In other words, the second dummy layer 54B is sandwiched between the etch stop layers 56E.

In some embodiments, the etch stop layers 56E are formed of a same material as the semiconductor layers 56 using the same or similar formation method. In the illustrated embodiment, the etch stop layers 56E are formed to be thinner than the dummy layers 54 and the semiconductor layers 56. For example, the etch stop layers 56E may have a thickness that is 20%, 10%, or less, of the thickness of the dummy layers 54 (or the semiconductor layers 56).

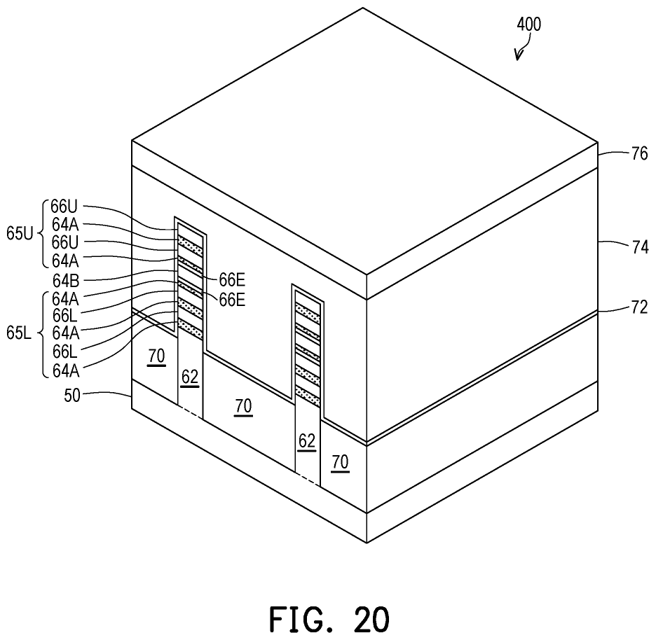

FIG. 20 shows the CFET device 400, after the patterning process (see FIG. 3) to form fins 62, nanostructures 66 and 64, and after formation of the dummy dielectric layer 72, dummy gate layer 74, and mask layer 76. After the patterning process, the patterned dummy layers 54 form nanostructures 64, the patterned semiconductor layers 56 form nanostructures 66, and the patterned ESLs 56E form ESLs 66E.

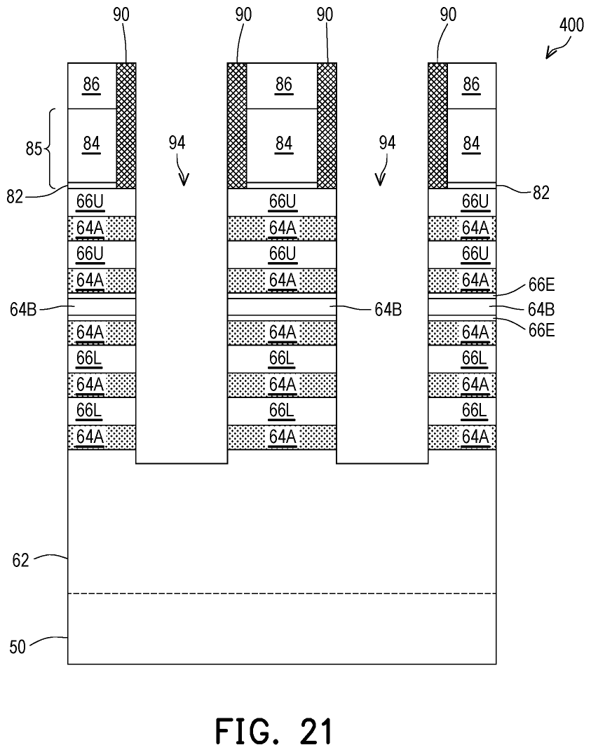

Next, in FIG. 21, the dummy gates 84 and dummy dielectrics 82 are formed by patterning the dummy gate layer 74 and the dummy dielectric layer 72, respectively. Gate spacers 90 are formed along sidewalls of the dummy gates 84 and dummy dielectrics 82. Next, source/drain recesses 94 are formed.

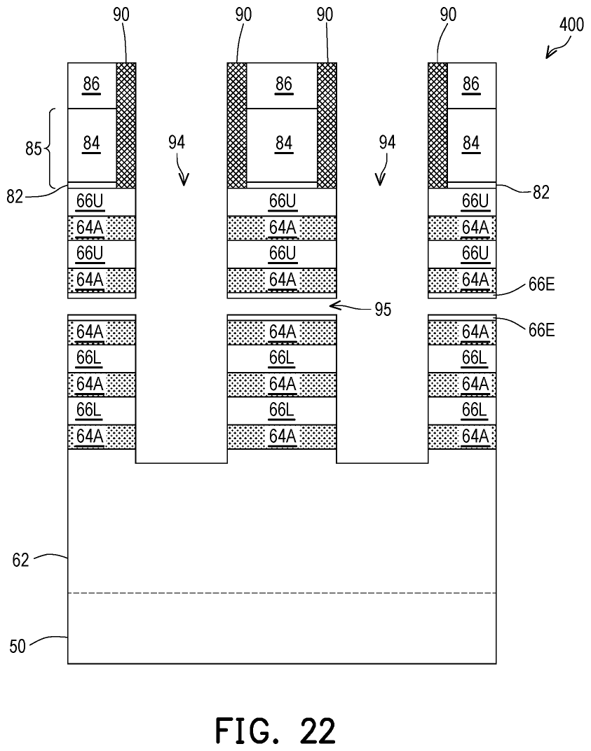

Next, in FIG. 22, the second dummy nanostructures 64B are removed by a selective etching process. Note that the ESLs 66E protect (e.g., shield) the dummy nanostructures 64A adjacent to the second dummy nanostructures 64B during the selective etching process, thereby reducing or avoiding unintended etching of the dummy nanostructures 64A. Therefore, the ESLs 66E help to retain target dimensions of the gaps 95, which in turn determines the dimensions of the subsequently formed isolation structures 100.

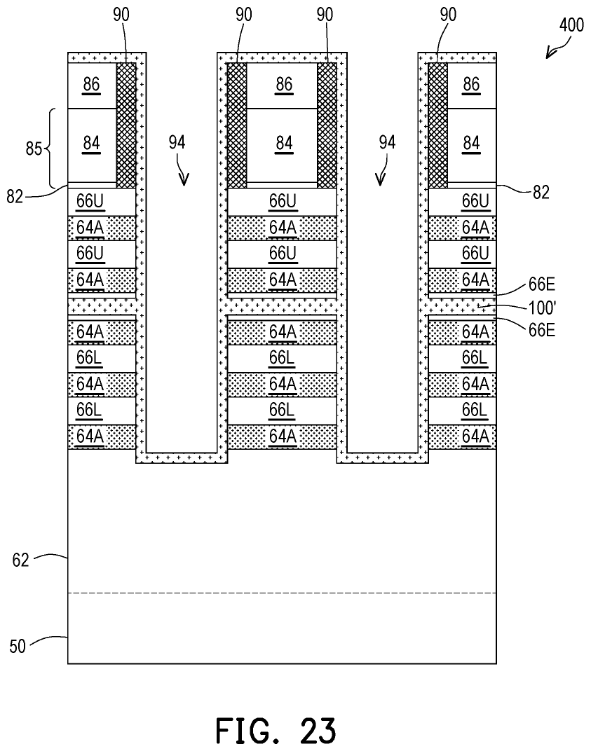

Next, in FIG. 23, the dielectric material 110′ is formed to fill the gaps 95 between the ESLs 66E, and to line the sidewalls and bottoms of the source/drain recesses 94.

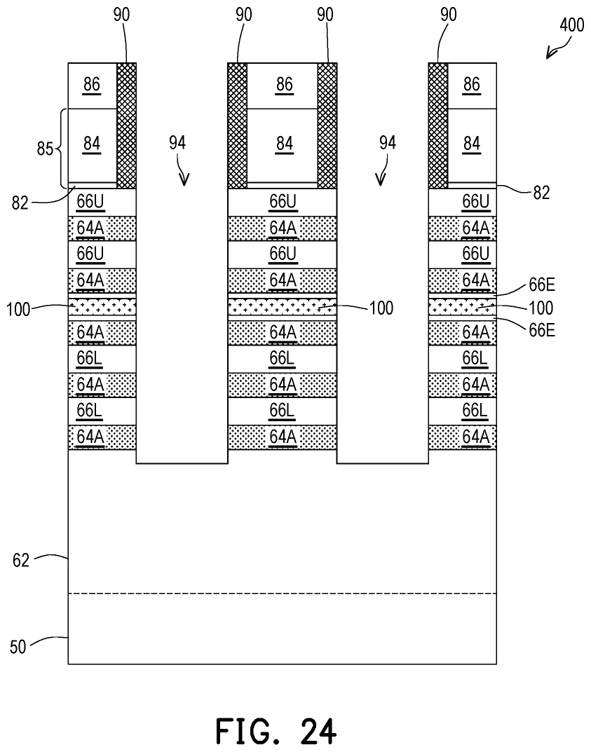

Next, in FIG. 24, an etching process(es) is performed to remove portions of the dielectric material 110′ outside of the gaps 95, and the remaining portions of the dielectric material 110′ form isolation structures 100, which are sandwiched between the ESLs 66E.

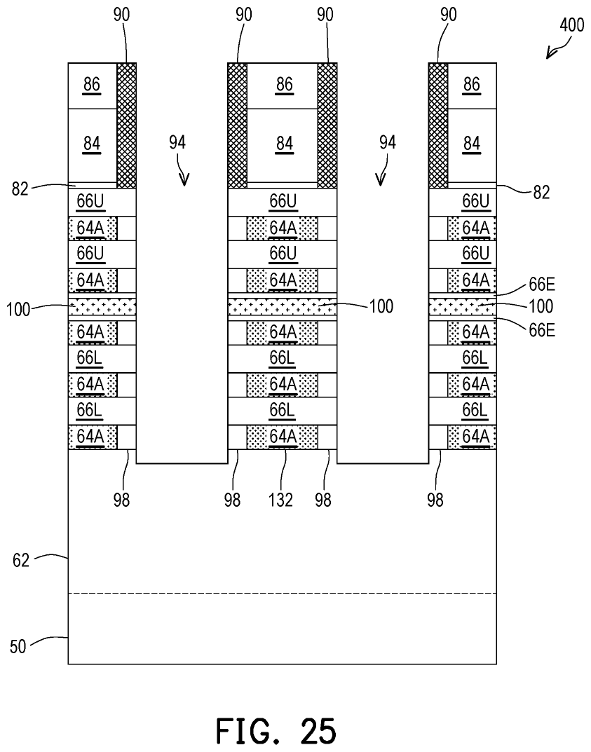

Next, in FIG. 25, inner spacers 98 are formed by replacing end portions of the first dummy nanostructures 64 exposed to the source/drain recesses 94.

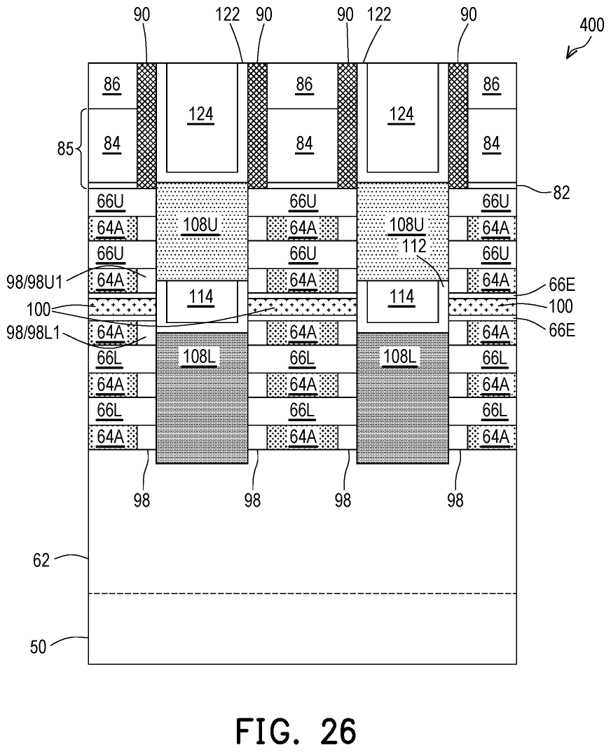

Next, in FIG. 26, lower epitaxial source/drain regions 108L, the first CESL 112, the first ILD 114, the upper epitaxial source/drain regions 108U, the second CESL 122, the second ILD 124 are formed successively in the source/drain recesses 94.

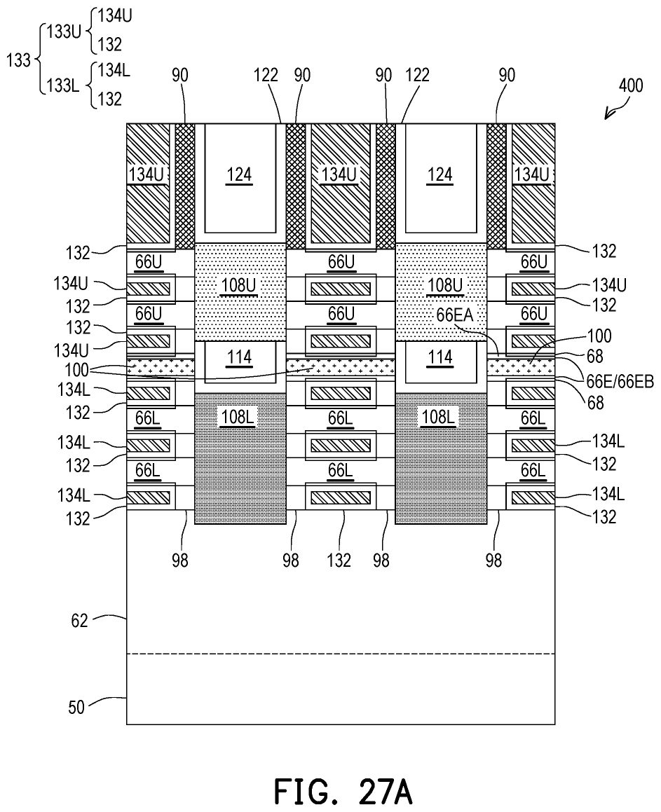

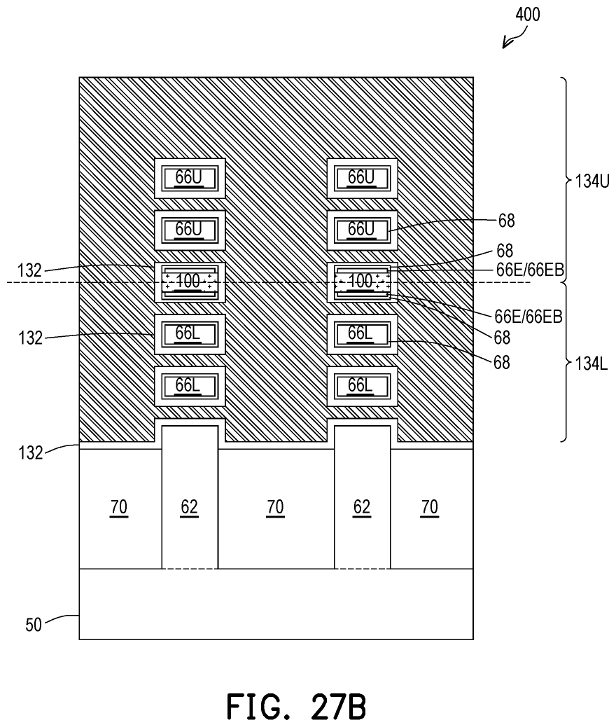

Next, in FIGS. 27A and 27B, the dummy gates 84 and dummy dielectrics 82 are removed, and subsequently, the first dummy nanostructures 64A are removed to release the nanostructures 66, therefore forming the channel regions of the CFET device. Note that after removal of the first dummy nanostructures 64A, end portions 66EA (portions contacting and extending along inner spacers 98) of the ESLs 66 E are not exposed to the openings between the nanostructures 66, while center portions 66EB of the ESLs 66E are exposed to the openings between the nanostructures 66.

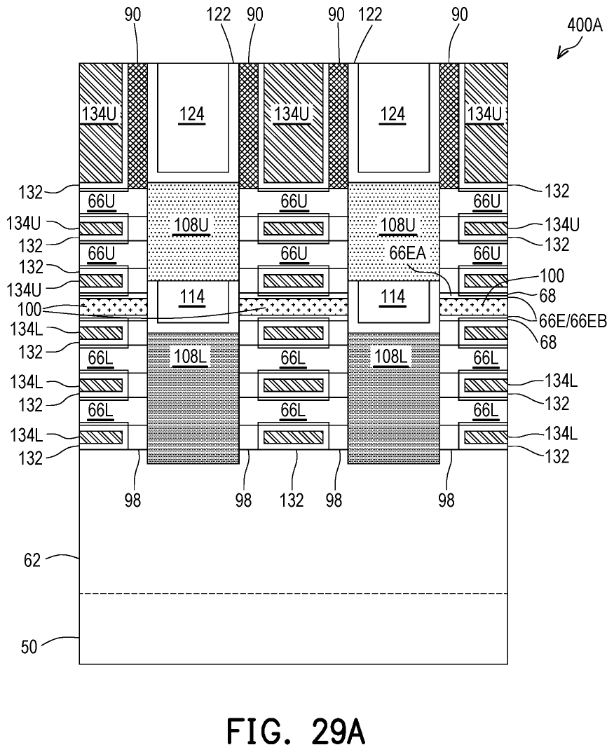

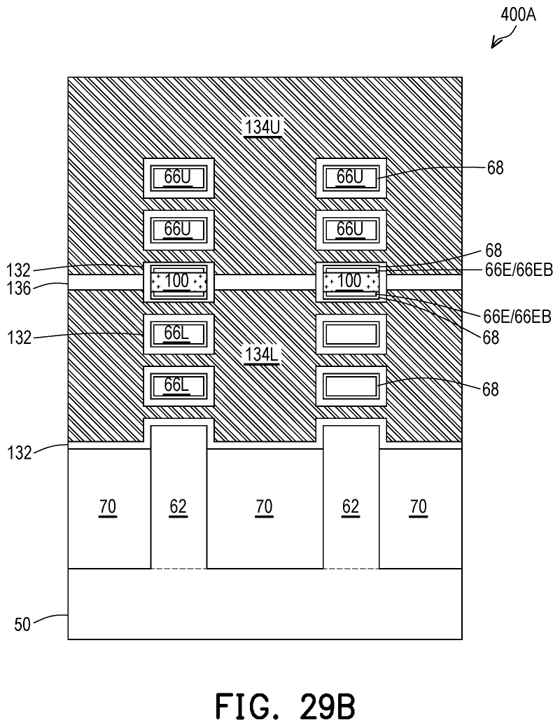

Next, the interfacial layer 68 is formed, e.g., by converting exterior portions of the nanostructures 66 into an oxide (e.g., silicon oxide) using an oxidization process. Note that in the illustrated embodiments, the ESLs 66E are formed of the same material as the nanostructures 66, and therefore, exterior portions of the ESLs 66E that are exposed to the openings between the nanostructures 66 are also converted into the interfacial layer 68 (e.g., silicon oxide) by the oxidization process. In the example of FIGS. 29A and 29B, interior portions (e.g., portions contacting the isolation structures 100) of the ESLs 66E are not oxidized, and remain as the semiconductor material (e.g., silicon) of the nanostructures 66. In particular, the end portions 66EA of the ESLs 66E, which are disposed between, and contacting, vertically adjacent inner spacers 98, are not oxidized. In contrast, center portions 66EB of the ESLs 66E are exposed to the openings 128, and therefore, exterior portions (e.g., outer sublayers) of the center portions 66EB are converted into the interfacial layer 68.

In FIG. 27B, the interfacial layer 68 on each of the nanostructures 66 encircles the nanostructure 66, and has a rectangular annular shape. In contrast, the interfacial layer 68 is disposed only on the upper surface and the lower surface of the isolation structure, and has a U-shape. The U-shaped interfacial layer 68 on the upper surface (or lower surface) of each isolation structure 100 extends along the upper surface and sidewalls of the remaining portions (e.g., interior portions) of the ESL 66 E.

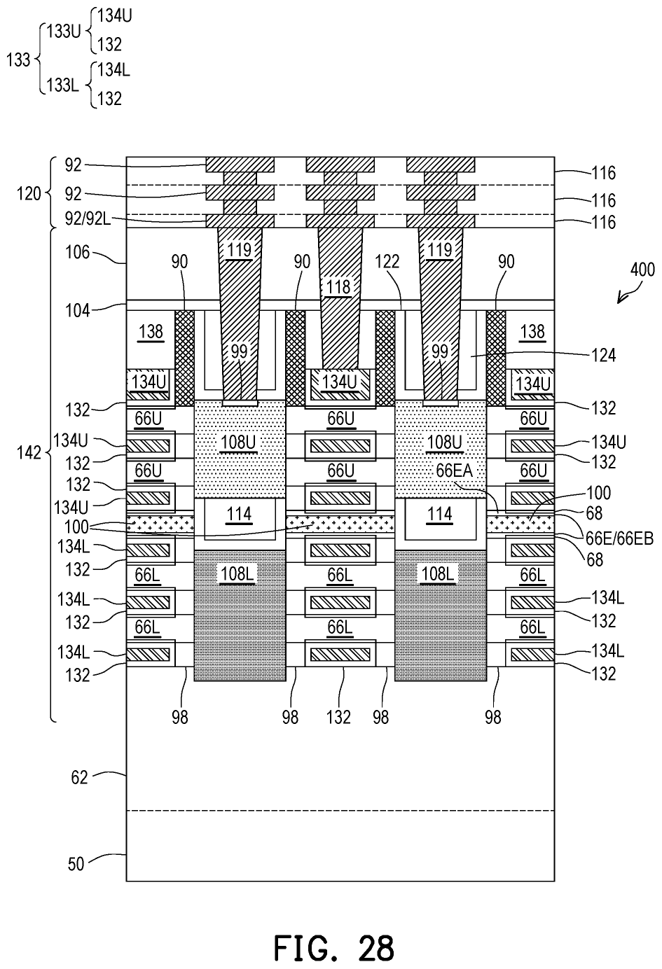

Next, in FIG. 28, gate masks 138 are formed over the gate structures 133. The ESL 104 and the third ILD 106 are formed over the gate masks 138 and the second ILD 124. Source/drain contact plugs 119 and gate contact plugs 118 are formed to electrically couple to the upper epitaxial source/drain regions 108U and the upper gate electrode 134U, respectively. Silicide regions 99 may be formed between the upper epitaxial source/drain regions 108U and the source/drain contact plugs 119. Next, the front-side interconnect structure 120 is formed on the device layer 142.

FIGS. 29A and 29B are cross-sectional views of a CFET device 400A, in accordance with another embodiment. The CFET device 400A is similar to the CFET device 400, but with the isolation layer 136 formed between the upper gate electrode 134U and the lower gate electrode 134L. The isolation layer 136 may be formed of a same or similar material of the isolation layer 136 in FIG. 14, using a same or similar formation method, details are not repeated here.

Additional embodiments are discussed hereinafter. The additional embodiment CFET devices may be formed by modifying the processing steps for the fabrication of CFET device 400. Skilled artisan, upon reading the present disclosure, would readily be able to modify the processing steps for the fabrication of CFET device 400 to form the additional embodiment CFET devices. Note that for each of the subsequent embodiments discussed, the isolation layer 136 between the lower gate electrode 134L and the upper gate electrode 134U, if present, may be removed to represent another embodiment, as skilled artisans readily appreciate.

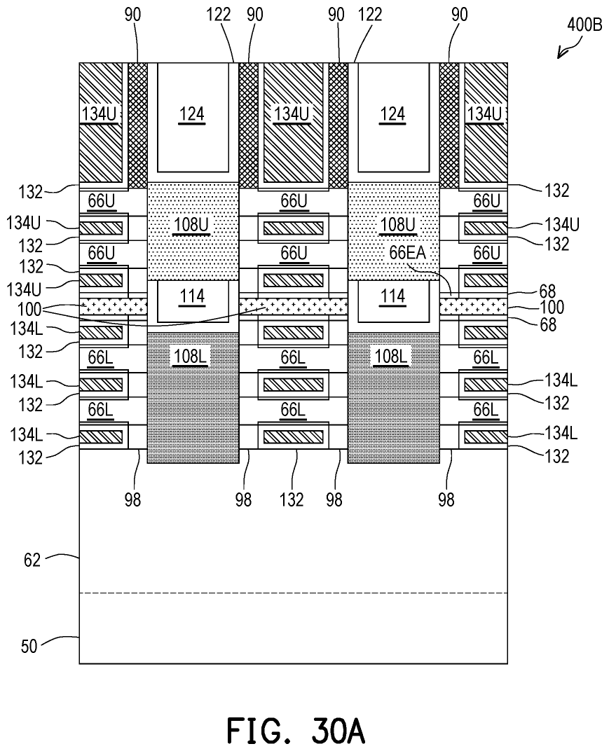

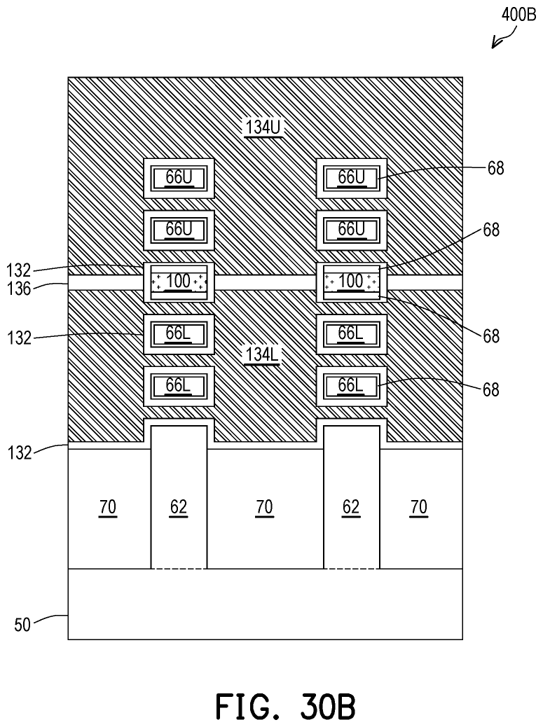

FIGS. 30A and 30B are cross-sectional views of a CFET device 400B, in accordance with another embodiment. The CFET device 400B is similar to the CFET device 400A, but the center portions 66EB of the ESLs 66E are completely oxidized into the interfacial layer 68. Note that as illustrated in FIG. 30A, the end portions 66EA of the ESLs 66E still remain un-oxidized. As a result of the complete oxidization of the center portions 66EB, in FIG. 30B, the interfacial layer 68 on the upper surface (or the lower surface) of each isolation structure 100 has a rectangular shape, and there is no un-oxidized ESL 66E left between the interfacial layer 68 and the isolation structure 100.

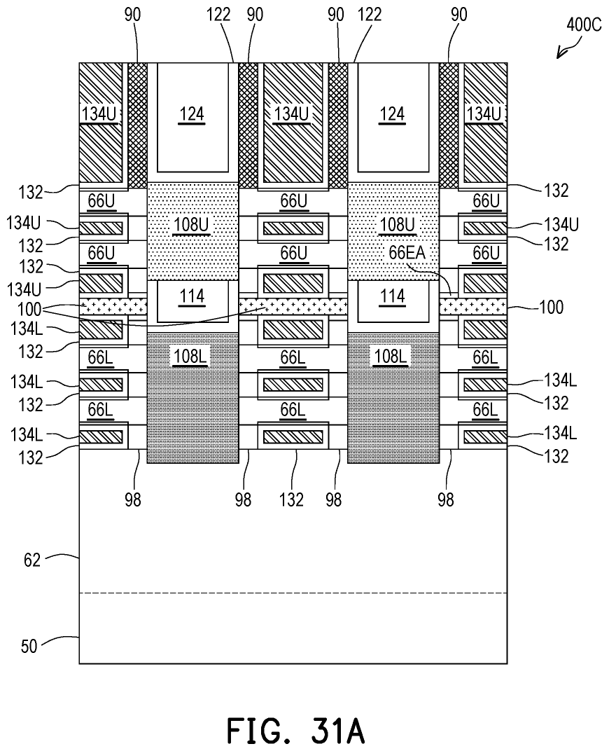

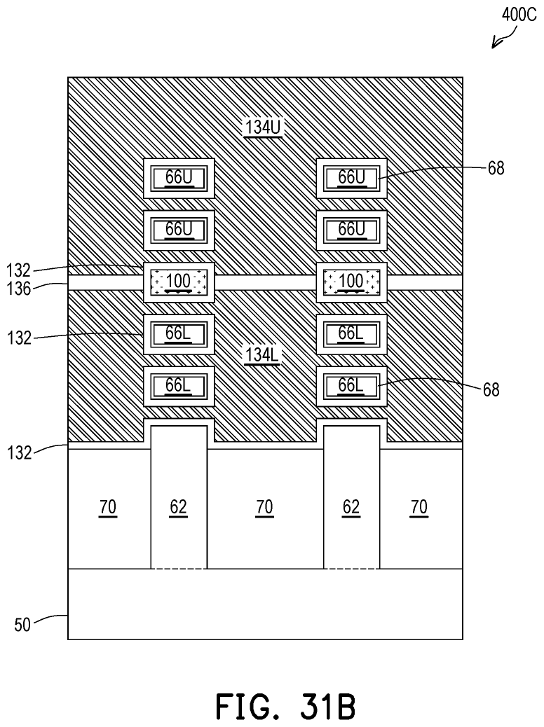

FIGS. 31A and 31B are cross-sectional views of a CFET device 400C, in accordance with another embodiment. The CFET device 400C is similar to the CFET device 400A, but no interfacial layer 68 is formed on the isolation structures 100. In some embodiments, in the processing of FIGS. 27A and 27B, the etching process performed to remove the first dummy nanostructures 64A also removes (e.g., completely removes) the center portions 66EB of the ESLs 66E, since the center portions 66EB are exposed to the openings between the nanostructures 66. As a result, no interfacial layer 68 is formed on the isolation structures 100. Note that as illustrated in FIG. 31A, the end portions 66EA of the ESLs 66E remain, because the end portions 66EA are not exposed to the openings between the nanostructures 66, thus are not removed or oxidized. In the cross-sectional view of FIG. 31B, which shows a cross-section across a middle of the isolation structures 100, no interfacial layer 68 is formed on the isolation structures 100.

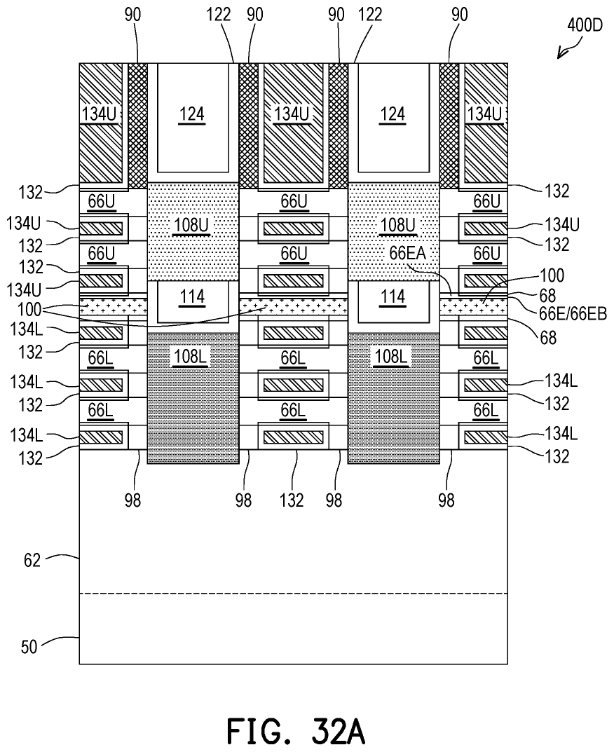

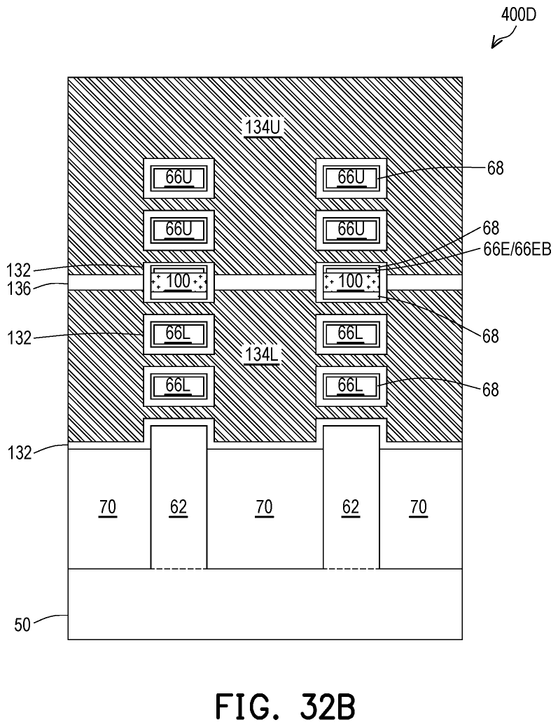

FIGS. 32A and 32B are cross-sectional views of a CFET device 400D, in accordance with another embodiment. The CFET device 400D is similar to the CFET device 400A, but the extent of oxidization is different for the ESLs 66E on the upper surface and the lower surface of the isolation structures 100. In the example of FIGS. 32A and 32B, the center portions 66EB of the ESLs 66E disposed on the lower surfaces of the isolation structures 100 are completely oxidized and turned into the interfacial layer 68, whereas the center portions 66EB of the ESLs 66E disposed on the upper surfaces of the isolation structures 100 are partially oxidized (e.g., only exterior portions are oxidized). As a result, in the cross-sectional view of FIG. 32B, the interfacial layer 68B on the upper surface of each isolation structure 100 has a U-shape, and extends along the upper surface and sidewalls of the remaining interior portion of the center portion 66EB of the ESL 66E. In contrast, the interfacial layer 68B on the lower surface of each isolation structure 100 has a rectangular shape, and there is no ESL 66E between the interfacial layer 68 and the isolation structure 100 in FIG. 32B.

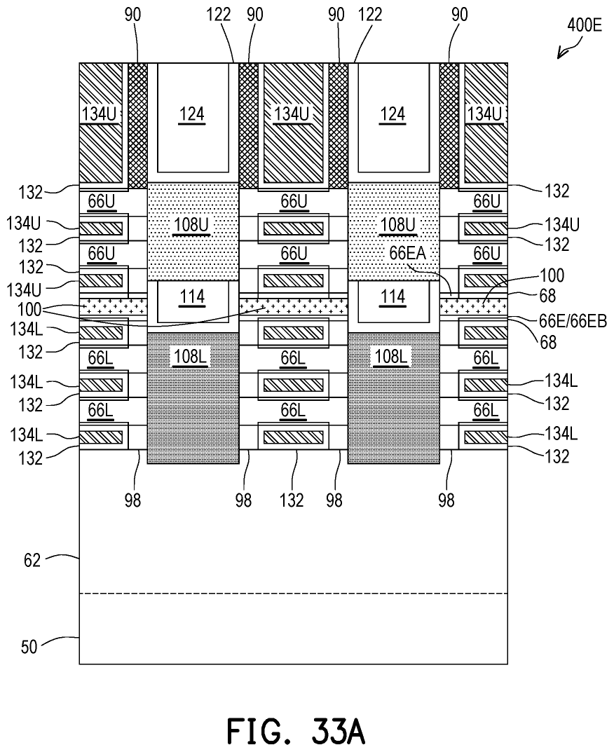

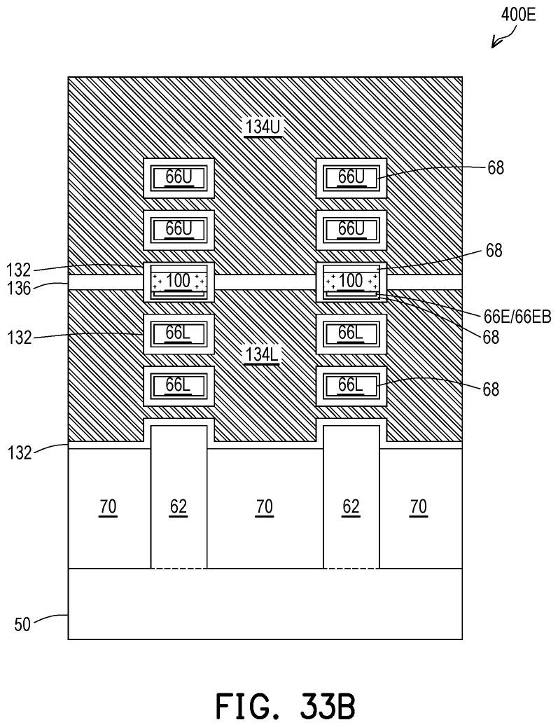

FIGS. 33A and 33B are cross-sectional views of a CFET device 400E, in accordance with yet another embodiment. The CFET device 400E is similar to the CFET device 400A, but the extent of oxidization is different for the ESLs 66 E on the upper surface and the lower surface of the isolation structures. In the example of FIGS. 33A and 33B, the center portions 66EB of the ESLs 66E disposed on the upper surfaces of the isolation structures 100 are completely oxidized and turned into the interfacial layer 68, whereas the center portions 66EB of the ESLs 66E disposed on the lower surfaces of the isolation structures 100 are partially oxidized (e.g., only exterior portions are oxidized). As a result, in the cross-sectional view of FIG. 33B, the interfacial layer 68B on the lower surface of each isolation structure 100 has a U-shape, and extends along the upper surface and sidewalls of the remaining interior portion of the center portion 66EB of the ESL 66E. In contrast, the interfacial layer 68B on the upper surface of each isolation structure 100 has a rectangular shape, and there is no ESL 66E between the interfacial layer 68 and the isolation structure 100 in FIG. 33B.

Embodiments may achieve advantages. The disclosed methods allow for various shapes and structures for the isolation structures 100 to satisfy different design target and performance requirements. For example, the bi-layered structure for the isolation structures 100, by using an etch resistant outer layer and a flowable inner layer, avoids or reduces seams in the isolation structure while still achieving desirable physical properties for the isolation structure. The dual-layered structure also provides more tuning parameters to tune the dielectric constant of the isolation structures. As another example, by using the ESLs 66E on both sides of the second dummy nanostructures 64B, the first dummy nanostructures 64A are protected from unwanted etching when the second dummy nanostructures 64B are removed, thereby retaining desired dimensions for the gaps 95, which in turn ensures that the isolation structures 100 formed in the gaps 95 have the target dimensions to achieve performance targets.

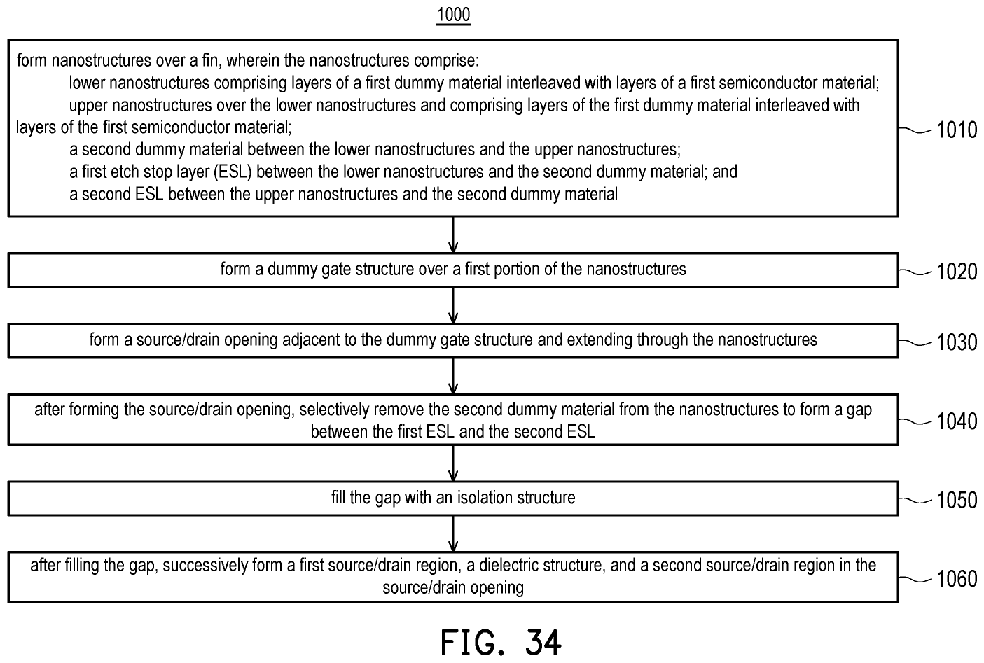

FIG. 34 is a flow chart of a method 1000 of forming a CFET device, in accordance with some embodiments. It should be understood that the embodiment method shown in FIG. 34 is merely an example of many possible embodiment methods. One of ordinary skill in the art would recognize many variations, alternatives, and modifications. For example, various steps as illustrated in FIG. 34 may be added, removed, replaced, rearranged, or repeated.

Referring to FIG. 34, at block 1010, nanostructures are formed over a fin, wherein the nanostructures comprise: lower nanostructures comprising layers of a first dummy material interleaved with layers of a first semiconductor material; upper nanostructures over the lower nanostructures and comprising layers of the first dummy material interleaved with layers of the first semiconductor material; a second dummy material between the lower nanostructures and the upper nanostructures; a first etch stop layer (ESL) between the lower nanostructures and the second dummy material; and a second ESL between the upper nanostructures and the second dummy material. At block 1020, a dummy gate structure is formed over a first portion of the nanostructures. At block 1030, a source/drain opening is formed adjacent to the dummy gate structure and extending through the nanostructures. At block 1040, after forming the source/drain opening, the second dummy material is selectively removed from the nanostructures to form a gap between the first ESL and the second ESL. At block 1050, the gap is filled with an isolation structure. At block 1060, after filling the gap, a first source/drain region, a dielectric structure, and a second source/drain region are successively formed in the source/drain opening.

In an embodiment, a method of forming a complementary field-effect transistor (CFET) device includes forming nanostructures over a fin, wherein the nanostructures comprise: lower nanostructures comprising layers of a first dummy material interleaved with layers of a first semiconductor material; upper nanostructures over the lower nanostructures and comprising layers of the first dummy material interleaved with layers of the first semiconductor material; a second dummy material between the lower nanostructures and the upper nanostructures; a first etch stop layer (ESL) between the lower nanostructures and the second dummy material; and a second ESL between the upper nanostructures and the second dummy material. The method further includes: forming a dummy gate structure over a first portion of the nanostructures; forming a source/drain opening adjacent to the dummy gate structure and extending through the nanostructures; after forming the source/drain opening, selectively removing the second dummy material from the nanostructures to form a gap between the first ESL and the second ESL; filling the gap with an isolation structure; and after filling the gap, successively forming a first source/drain region, a dielectric structure, and a second source/drain region in the source/drain opening. In an embodiment, the first ESL, the second ESL, and the first semiconductor material are formed of a same semiconductor material, wherein the first ESL and the second ESL are formed to be thinner than the layers of the first semiconductor material of the nanostructures. In an embodiment, the first dummy material and the second dummy material are formed of semiconductor materials with different compositions. In an embodiment, the method further includes, after filing the gap and before the successively forming: replacing end portions of the first dummy material of the nanostructures exposed by the source/drain opening with inner spacers, wherein after filling the gap, the dielectric structure extends along a sidewall of the isolation structure, along a first sidewall of a first inner spacer, and along a second sidewall of a second inner spacer, wherein the first inner spacer is below the isolation structure and contacts the first ESL, and the second inner spacer is above the isolation structure and contacts the second ESL, wherein the dielectric structure is disposed between an upper surface of the second inner spacer distal from the fin and a lower surface of the first inner spacer facing the fin. In an embodiment, the method further includes, after forming the second source/drain region: removing the dummy gate structure to expose the first portion of the nanostructures; after removing the dummy gate structure, selectively removing the first dummy material from the first portion of the nanostructures, wherein after selectively removing the first dummy material, the first semiconductor material in the upper and lower nanostructures of the first portion of the nanostructures form upper channel regions and lower channel regions of the CFET device, respectively; performing an oxidization process to convert at least exterior portions of the upper channel regions, exterior portions of the lower channel regions, exterior portions of the second ESL, and exterior portions of the first ESL into an interfacial layer; and after performing the oxidization process, forming a first gate structure around the lower channel regions and forming a second gate structure around the upper channel regions. In an embodiment, interior portions of at least one of the first ESL and the second ESL remain as the semiconductor material after the oxidization process. In an embodiment, the method further includes forming an isolation layer between the first gate structure and the second gate structure.

In an embodiment, a complementary field-effect transistor (CFET) device includes: a fin; a first plurality of channel regions disposed vertically over the fin; a second plurality of channel regions disposed vertically over the first plurality of channel regions; an isolation structure between the first plurality of channel regions and the second plurality of channel regions; a first etch stop layer (ESL) on a lower surface of the isolation structure facing the fin; a second ESL on an upper surface of the isolation structure distal from the fin, wherein the first ESL, the second ESL, the first plurality of channel regions, and the second plurality of channel regions are a same semiconductor material; first source/drain regions at opposing ends of the first plurality of channel regions; second source/drain regions at opposing ends of the second plurality of channel regions; dielectric structures at opposing ends of the isolation structure and disposed vertically between the first source/drain regions and the second source/drain regions; a first gate structure around the first plurality of channel regions; and a second gate structure around the second plurality of channel regions. In an embodiment, the first ESL and the second ESL are thinner than the first plurality of channel regions and the second plurality of channel regions. In an embodiment, the CFET device further includes: first inner spacers disposed laterally between the first gate structure and the first source/drain regions; and second inner spacers disposed laterally between the second gate structure and the second source/drain regions. In an embodiment, the dielectric structures contact and extend along sidewalls of the isolation structure, sidewalls of the first ESL, sidewalls of the second ESL, sidewalls of uppermost ones of the first inner spacers, and sidewalls of lowermost ones of the second inner spacers. In an embodiment, an upper surface of the dielectric structures distal from the fin is closer to the fin than a lowermost surface of the second plurality of channel regions facing the fin, wherein a lower surface of the dielectric structures facing the fin is further from the fin than an uppermost surface of the first plurality of channel regions distal from the fin. In an embodiment, the CFET device further includes: a first interfacial layer embedded in the first ESL between the isolation structure and the first gate structure; and a second interfacial layer embedded in the second ESL between the isolation structure and the second gate structure, wherein the first interfacial layer and the second interfacial layer are an oxide of the semiconductor material of the first ESL. In an embodiment, end portions of the isolation structure are in contact with the dielectric structures, wherein a middle portion of the isolation structure is disposed laterally between the end portions of the isolation structure, wherein a first portion of the first ESL extends along the end portions of the isolation structure, and a second portion of the first ESL extends along the middle portion of the isolation structure, wherein the first portion of the first ESL is thicker than the second portion of the ESL. In an embodiment, in a cross-section along a longitudinal direction of the first plurality of channel regions, the first interfacial layer has a same thickness as the first ESL, or the second interfacial layer has a same thickness as the second ESL. In an embodiment, in a cross-section along a longitudinal direction of the first plurality of channel regions, the first interfacial layer has a smaller thickness than the first ESL, or the second interfacial layer has a smaller thickness that the second ESL.

In an embodiment, a complementary field-effect transistor (CFET) device includes: a substrate; a fin protruding above the substrate; first channel regions vertically stacked over the fin; second channel regions vertically stacked over the first channel regions; an isolation structure between the first channel regions and the second channel regions; a first gate structure around the first channel regions; a second gate structure around the second channel regions; a first etch stop layer (ESL) extending along a lower surface of the isolation structure facing the substrate; a second ESL extending along an upper surface of the isolation structure distal from the substrate, wherein the first channel regions, the second channel regions, the first ESL, and the second ESL are a semiconductor material; a first interfacial layer embedded in the first ESL between the isolation structure and the first gate structure; a second interfacial layer embedded in the second ESL between the isolation structure and the second gate structure, wherein the first interfacial layer and the second interfacial layer are an oxide of the semiconductor material; first source/drain regions at opposing ends of the first channel regions; second source/drain regions at opposing ends of the second channel regions; and dielectric structures at opposing ends of the isolation structure, wherein the dielectric structures separate the first source/drain regions and the second source/drain regions. In an embodiment, in a cross-section along a direction perpendicular to a longitudinal direction of the first channel regions, a first one of the first interfacial layer and the second interfacial layer has a U-shape. In an embodiment, in the cross-section, a second one of the first interfacial layer and the second interfacial layer has a rectangular shape. In an embodiment, in a cross-section along a direction perpendicular to a longitudinal direction of the first channel regions, a first one of the first interfacial layer and the second interfacial layer has a rectangular shape.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a complementary field-effect transistor (CFET) device, the method comprising:
forming nanostructures over a fin, wherein the nanostructures comprise:
lower nanostructures comprising layers of a first dummy material interleaved with layers of a first semiconductor material;
upper nanostructures over the lower nanostructures and comprising layers of the first dummy material interleaved with layers of the first semiconductor material;
a second dummy material between the lower nanostructures and the upper nanostructures;
a first etch stop layer (ESL) between the lower nanostructures and the second dummy material; and
a second ESL between the upper nanostructures and the second dummy material;
forming a dummy gate structure over a first portion of the nanostructures;
forming a source/drain opening adjacent to the dummy gate structure and extending through the nanostructures;
after forming the source/drain opening, selectively removing the second dummy material from the nanostructures to form a gap between the first ESL and the second ESL;
filling the gap with an isolation structure; and
after filling the gap, successively forming a first source/drain region, a dielectric structure, and a second source/drain region in the source/drain opening.

2. The method of claim 1, wherein the first ESL, the second ESL, and the first semiconductor material are formed of a same semiconductor material, wherein the first ESL and the second ESL are formed to be thinner than the layers of the first semiconductor material of the nanostructures.

3. The method of claim 2, wherein the first dummy material and the second dummy material are formed of semiconductor materials with different compositions.

4. The method of claim 2, further comprising, after filing the gap and before the successively forming:
replacing end portions of the first dummy material of the nanostructures exposed by the source/drain opening with inner spacers, wherein after filling the gap, the dielectric structure extends along a sidewall of the isolation structure, along a first sidewall of a first inner spacer, and along a second sidewall of a second inner spacer, wherein the first inner spacer is below the isolation structure and contacts the first ESL, and the second inner spacer is above the isolation structure and contacts the second ESL, wherein the dielectric structure is disposed between an upper surface of the second inner spacer distal from the fin and a lower surface of the first inner spacer facing the fin.

5. The method of claim 2, further comprising, after forming the second source/drain region:
removing the dummy gate structure to expose the first portion of the nanostructures;
after removing the dummy gate structure, selectively removing the first dummy material from the first portion of the nanostructures, wherein after selectively removing the first dummy material, the first semiconductor material in the upper and lower nanostructures of the first portion of the nanostructures form upper channel regions and lower channel regions of the CFET device, respectively;
performing an oxidization process to convert at least exterior portions of the upper channel regions, exterior portions of the lower channel regions, exterior portions of the second ESL, and exterior portions of the first ESL into an interfacial layer; and
after performing the oxidization process, forming a first gate structure around the lower channel regions and forming a second gate structure around the upper channel regions.

6. The method of claim 5, wherein interior portions of at least one of the first ESL and the second ESL remain as the semiconductor material after the oxidization process.

7. The method of claim 5, further comprising forming an isolation layer between the first gate structure and the second gate structure.

8. A complementary field-effect transistor (CFET) device comprising:
a fin;
a first plurality of channel regions disposed vertically over the fin;
a second plurality of channel regions disposed vertically over the first plurality of channel regions;
an isolation structure between the first plurality of channel regions and the second plurality of channel regions;
a first etch stop layer (ESL) on a lower surface of the isolation structure facing the fin;
a second ESL on an upper surface of the isolation structure distal from the fin, wherein the first ESL, the second ESL, the first plurality of channel regions, and the second plurality of channel regions are a same semiconductor material;
first source/drain regions at opposing ends of the first plurality of channel regions;
second source/drain regions at opposing ends of the second plurality of channel regions;
dielectric structures at opposing ends of the isolation structure and disposed vertically between the first source/drain regions and the second source/drain regions;
a first gate structure around the first plurality of channel regions; and
a second gate structure around the second plurality of channel regions.

9. The CFET device of claim 8, wherein the first ESL and the second ESL are thinner than the first plurality of channel regions and the second plurality of channel regions.

10. The CFET device of claim 8, further comprising:
first inner spacers disposed laterally between the first gate structure and the first source/drain regions; and
second inner spacers disposed laterally between the second gate structure and the second source/drain regions.

11. The CFET device of claim 10, wherein the dielectric structures contact and extend along sidewalls of the isolation structure, sidewalls of the first ESL, sidewalls of the second ESL, sidewalls of uppermost ones of the first inner spacers, and sidewalls of lowermost ones of the second inner spacers.

12. The CFET device of claim 8, wherein an upper surface of the dielectric structures distal from the fin is closer to the fin than a lowermost surface of the second plurality of channel regions facing the fin, wherein a lower surface of the dielectric structures facing the fin is further from the fin than an uppermost surface of the first plurality of channel regions distal from the fin.

13. The CFET device of claim 8, further comprising:
a first interfacial layer embedded in the first ESL between the isolation structure and the first gate structure; and
a second interfacial layer embedded in the second ESL between the isolation structure and the second gate structure, wherein the first interfacial layer and the second interfacial layer are an oxide of the semiconductor material of the first ESL.

14. The CFET device of claim 13, wherein end portions of the isolation structure are in contact with the dielectric structures, wherein a middle portion of the isolation structure is disposed laterally between the end portions of the isolation structure, wherein a first portion of the first ESL extends along the end portions of the isolation structure, and a second portion of the first ESL extends along the middle portion of the isolation structure, wherein the first portion of the first ESL is thicker than the second portion of the ESL.

15. The CFET device of claim 13, wherein in a cross-section along a longitudinal direction of the first plurality of channel regions, the first interfacial layer has a same thickness as the first ESL, or the second interfacial layer has a same thickness as the second ESL.

16. The CFET device of claim 13, wherein in a cross-section along a longitudinal direction of the first plurality of channel regions, the first interfacial layer has a smaller thickness than the first ESL, or the second interfacial layer has a smaller thickness that the second ESL.

17. A complementary field-effect transistor (CFET) device comprising:
a substrate;
a fin protruding above the substrate;
first channel regions vertically stacked over the fin;
second channel regions vertically stacked over the first channel regions;
an isolation structure between the first channel regions and the second channel regions;
a first gate structure around the first channel regions;
a second gate structure around the second channel regions;
a first etch stop layer (ESL) extending along a lower surface of the isolation structure facing the substrate;
a second ESL extending along an upper surface of the isolation structure distal from the substrate, wherein the first channel regions, the second channel regions, the first ESL, and the second ESL are a semiconductor material;
a first interfacial layer embedded in the first ESL between the isolation structure and the first gate structure;
a second interfacial layer embedded in the second ESL between the isolation structure and the second gate structure, wherein the first interfacial layer and the second interfacial layer are an oxide of the semiconductor material;
first source/drain regions at opposing ends of the first channel regions;
second source/drain regions at opposing ends of the second channel regions; and
dielectric structures at opposing ends of the isolation structure, wherein the dielectric structures separate the first source/drain regions and the second source/drain regions.

18. The CFET device of claim 17, wherein in a cross-section along a direction perpendicular to a longitudinal direction of the first channel regions, a first one of the first interfacial layer and the second interfacial layer has a U-shape.

19. The CFET device of claim 18, wherein in the cross-section, a second one of the first interfacial layer and the second interfacial layer has a rectangular shape.

20. The CFET device of claim 17, wherein in a cross-section along a direction perpendicular to a longitudinal direction of the first channel regions, a first one of the first interfacial layer and the second interfacial layer has a rectangular shape.
